(19) United States
(12) Patent Application Publication
(10) Pub. No.: US 2026/0293422 A1
(43) Pub. Date: Sep. 24, 2026

(54) BORON-NITROGEN-CONTAINING ORGANIC COMPOUND AND APPLICATION THEREOF IN ORGANIC LIGHT-EMITTING DIODE DEVICE

(71) Applicant: BOE Technology Group Co., Ltd., Beijing (CN)

(72) Inventors: Mingli LIU, Beijing (CN); Xiaobo DU, Beijing (CN); Erli LI, Beijing (CN)

(21) Appl. No.: 19/479,793

(22) PCT Filed: Oct. 21, 2024
(86) PCT No.: PCT/CN2024/126176

§ 371 Date: Oct. 29, 2025

(30) Foreign Application Priority Data
Nov. 30, 2023 (CN) 202311635200.X

(51) Int. Cl. H10K 50/12; C07B 59/00; C07F 5/02; H10K 50/15; H10K 50/16; H10K 50/17; H10K 50/18; H10K 85/30; H10K 85/60; H10K 101/10; H10K 101/20; H10K 101/30

(52) U.S. Cl. CPC H10K 50/12; C07B 59/002; C07F 5/027; H10K 50/15; H10K 50/16; H10K 50/171; H10K 50/181; H10K 85/346; H10K 85/623; H10K 85/626; H10K 85/633; H10K 85/6572; H10K 85/658; C07B 2200/05; H10K 2101/10; H10K 2101/20; H10K 2101/30

(57) ABSTRACT

A boron-nitrogen-containing organic compound and an application thereof in an organic light-emitting diode device are provided. By introducing the silicon-containing substituent into a molecular planar skeleton, the overlapping is avoided by the silicon-containing substituent between dopants and/or between a dopant and a host, the lifetime of the triplet excitons is shortened, thereby improving the luminescence efficiency and/or prolonging the lifetime of the organic light-emitting diode device. Meanwhile, the silicon-containing substituent has a small influence on the highest occupied molecular orbital, the lowest unoccupied molecular orbital, the triplet state and the singlet state of the boron-nitrogen-containing organic compound, and can occupy a wider space due to the fact that the silicon-carbon bond is longer than the carbon-carbon bond, so that the boron-nitrogen-containing organic compound has a more stereoscopic structure, and the luminescence efficiency and the lifetime of the organic light-emitting diode device are improved through the more stereoscopic structure.

### CROSS REFERENCE TO RELATED APPLICATIONS

The present application claims the priority of the Chinese Patent Application No. 202311635200.X filed on Nov. 30, 2023, the content of which is incorporated herein by reference in its entirety.

### TECHNICAL FIELD

The present disclosure relates to the field of organic light-emitting diode device technology, and in particular to a boron-nitrogen-containing organic compound and an application thereof in an organic light-emitting diode device.

### BACKGROUND

In an organic light-emitting diode device, a material of an organic functional layer undergoes a development process from a fluorescent material to a phosphorescent material, and then to a thermally activated delayed fluorescence (TADF) material. The TADF material is a material that captures triplet excitons to singlet excitons by controlling a singlet-triplet splitting energy (ΔEₛₜ), which is small enough to convert the triplet excitons to the singlet excitons through reverse intersystem crossing (RISC).

In the related art, a molecular structure of the TADF material (B-N series TADF material) into which boron and nitrogen atoms are introduced has a high planarity, so that when the TADF material is applied to the organic light-emitting diode device, a dopant significantly easily overlaps with another dopant or a host, and therefore, triplet excitons of the TADF material are relatively stable, and the lifetime of the triplet excitons is increased, which results in the reduced luminescence efficiency or the shortened lifetime of the organic light-emitting diode device, thereby limiting the application of the TADF material of B-N series in the organic light-emitting diode device.

It is noted that the content disclosed in this background section is only for enhancement of understanding of the background of the present disclosure and therefore may include information that does not constitute prior art known to one of ordinary skill in the art.

### SUMMARY OF THE INVENTION

The technical problems of low luminescence efficiency or short lifetime of TADF materials of the B-N series can be solved to some extent by using one or more embodiments of the present disclosure.

The embodiment of the present disclosure provides a boron-nitrogen-containing organic compound, wherein the boron-nitrogen-containing organic compound has following structure in a general formula 1:

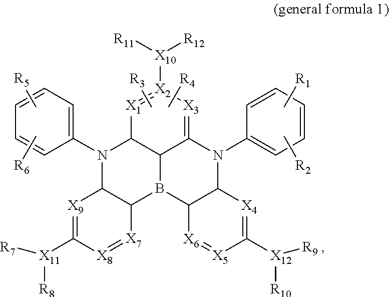

wherein at least one of R₁ to R₁₂ is a silicon-containing substituent; R₁ to R₁₂ are the same as each other or different from each other and are each independently selected from hydrogen, a substituted or unsubstituted alkyl group having 1 to 40 carbon atoms, a substituted or unsubstituted aryl group having 6 to 40 carbon atoms, a substituted or unsubstituted heteroaryl group having 5 to 60 carbon atoms, a substituted or unsubstituted fluorenyl group, a substituted or unsubstituted heterofluorenyl group, a substituted or unsubstituted aryloxy group having 6 to 60 carbon atoms, a substituted or unsubstituted alkoxy group having 1 to 39 carbon atoms, a substituted or unsubstituted arylamine group having 6 to 39 carbon atoms, a substituted or unsubstituted cycloalkyl group having 3 to 39 carbon atoms, a substituted or unsubstituted heterocycloalkyl group having 3 to 39 carbon atoms, a substituted or unsubstituted alkylsilyl group having 1 to 39 carbon atoms, a substituted or unsubstituted alkylboryl group having 1 to 39 carbon atoms, a substituted or unsubstituted arylboryl group having 6 to 39 carbon atoms, a substituted or unsubstituted arylphosphino group having 6 to 39 carbon atoms, and a substituted or unsubstituted arylsilyl group having 6 to 39 carbon atoms; R₁ and R² are bonded to form a ring, fused to form a ring, or do not form a ring, R₃ and R⁴ are bonded to form a ring, fused to form a ring, or do not form a ring, R₅ and R⁶ are bonded to form a ring, fused to form a ring, or do not form a ring, R₇ and R₅ are bonded to form a ring, fused to form a ring, or do not form a ring, R₉ and R₁₀ are bonded to form a ring, fused to form a ring, or do not form a ring, and R¹¹ and R¹² are bonded to form a ring, fused to form a ring, or do not form a ring; X₁ to X₁₂ are the same as each other or different from each other and are each independently selected from CH and N, and at least one of X₁₀ to X₁₂ is N; and the hydrogen in R₁ to R₁₂ and X₁ to X₁₂ is selected from any one or more of protium, deuterium and tritium.

As an alternative, in the general formula 1, R₁ to R₁₂ are independently selected from substituents containing 1 to 4 aromatic rings and/or aromatic heterocyclic rings.

As an alternative, in the general formula 1, R₁ and R₂ are bonded to form a 5 to 8-membered ring, and/or R₃ and R₄ are bonded to form a 5 to 8-membered ring, and/or R₅ and R₆ are bonded to form a 5 to 8-membered ring, and/or R₇ and R₅ are bonded to form a 5 to 8-membered ring, and/or R₉ and R₁₀ are bonded to form a 5 to 8-membered ring, and/or R₁₁ and R₁₂ are bonded to form a 5 to 8-membered ring.

As an alternative, in the general formula 1, X₁, X₃, X₄, X₅, X₈, X₉, X₁₀, X₁₁ and X₁₂ are the same as each other or different from each other and are independently selected from CD and N.

As an alternative, in the general formula 1, X₂, X₆, and X₇ are the same as each other or different from each other and are independently selected from CD and N.

As an alternative, the boron-nitrogen-containing organic compound has following structure in a general formula 2 or 3:

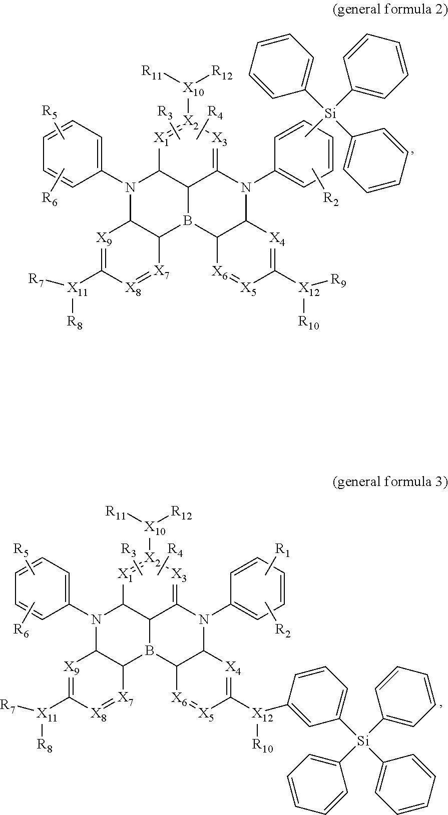

wherein in the general formulas 2 and 3, the definitions of R₁ to R₁₂ and X₁ to X₁₂ are the same as those in the general formula 1.

As an alternative, a singlet (E_{S1})-triplet (E_{T1}) splitting energy (ΔEₛₜ) of the boron-nitrogen-containing organic compound is greater than OeV and less than 1.0 eV.

As an alternative, the boron-nitrogen-containing organic compound satisfies: a triplet energy level (E_{T1}) is greater than or equal to 2.60 eV; a triplet excitation wavelength (λ_{T1}) is less than or equal to 480 nm; and a HOMO orbital energy level (E_{HOMO}) is greater than or equal to 4.60 eV.

As an alternative, the boron-nitrogen-containing organic compound is represented by any one of formulas 1 to 30:

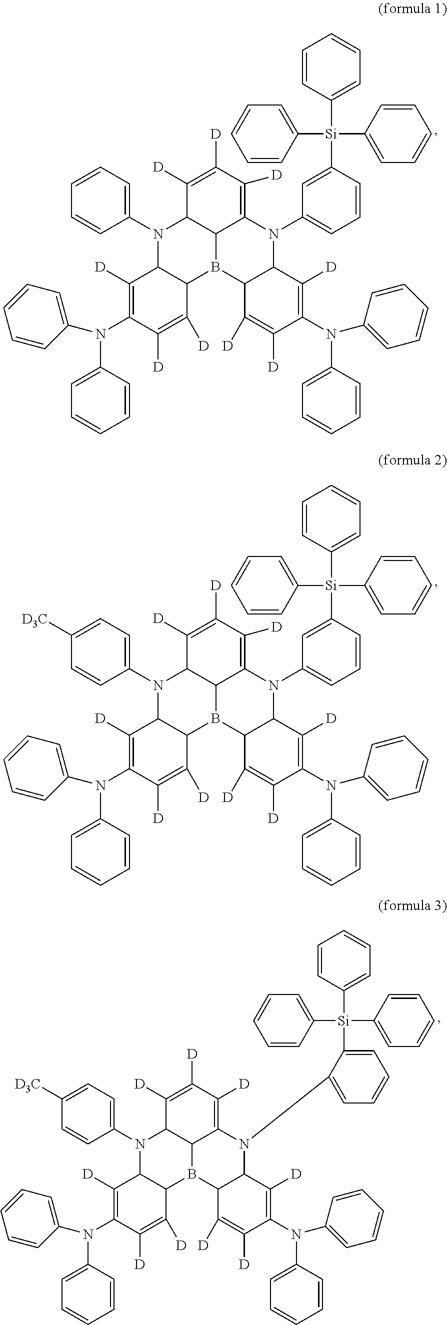

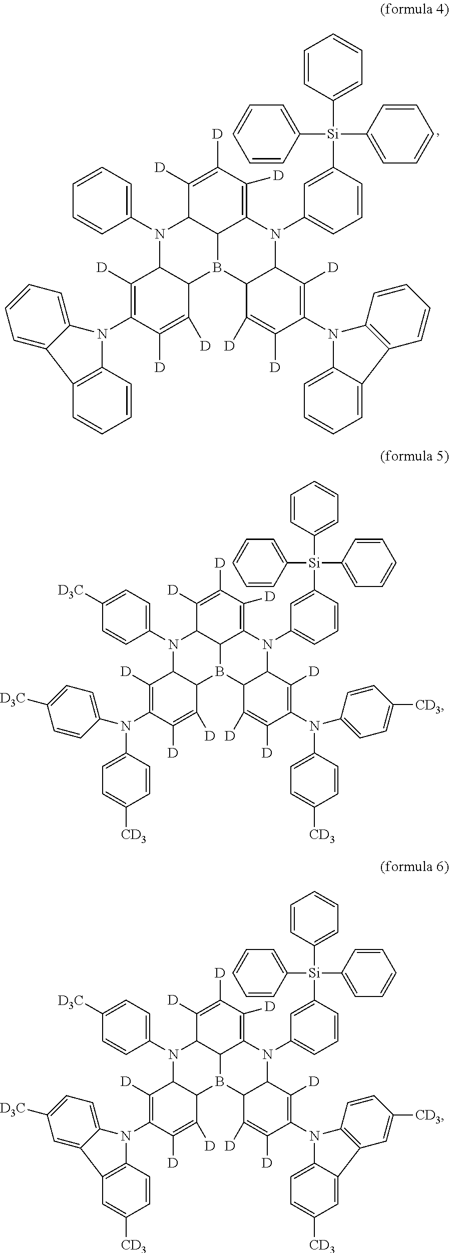

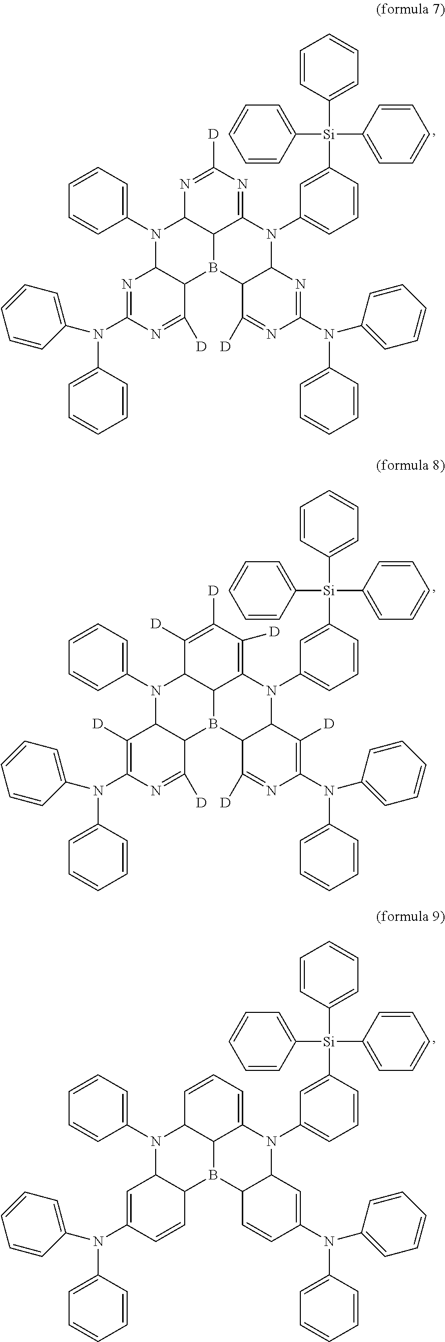 [SMILES: [2H]C1=NC2C3B(C4C([2H])=NC(N(c5ccccc5)c5ccccc5)=NC4N(c4cccc([Si](c5ccccc5)(c5ccccc5)c5ccccc5)c4)C3=N1)C1C([2H])=NC(N(c3ccccc3)c3ccccc3)=NC1N2c1ccccc1 ; [2H]C1=NC(N(c2ccccc2)c2ccccc2)=C([2H])C2C1B1C3C([2H])=NC(N(c4ccccc4)c4ccccc4)=C([2H])C3N(c3ccccc3)C3C([2H])=C([2H])C([2H])=C(C13)N2c1cccc([Si](c2ccccc2)(c2ccccc2)c2ccccc2)c1 ; C1=CC2C3B(C4C=CC(N(c5ccccc5)c5ccccc5)=CC4N(c4cccc([Si](c5ccccc5)(c5ccccc5)c5ccccc5)c4)C3=C1)C1C=CC(N(c3ccccc3)c3ccccc3)=CC1N2c1ccccc1]

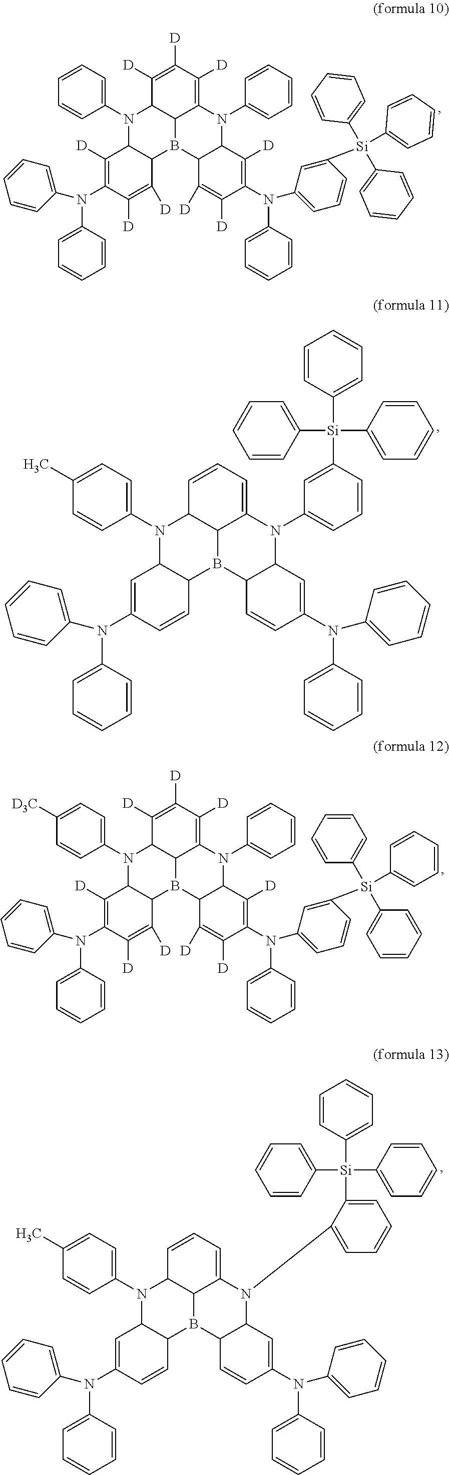

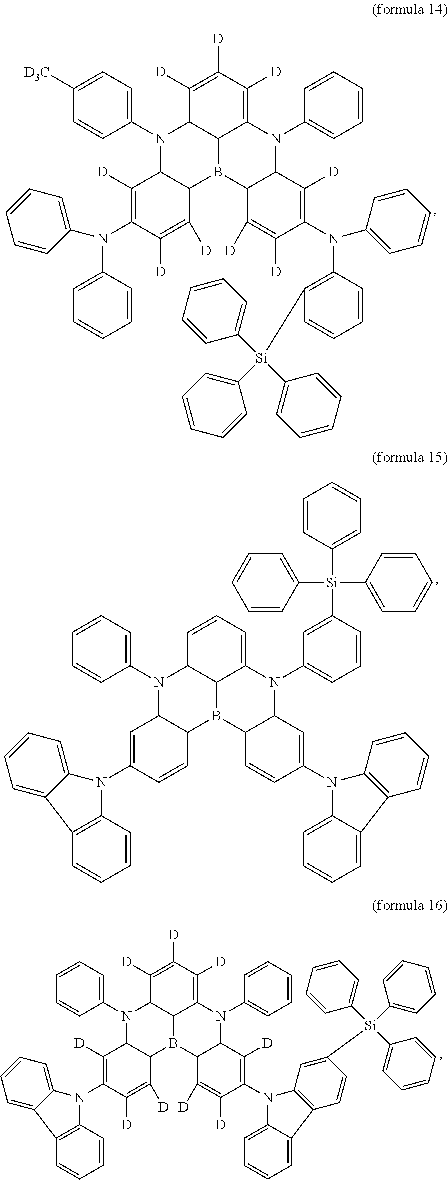

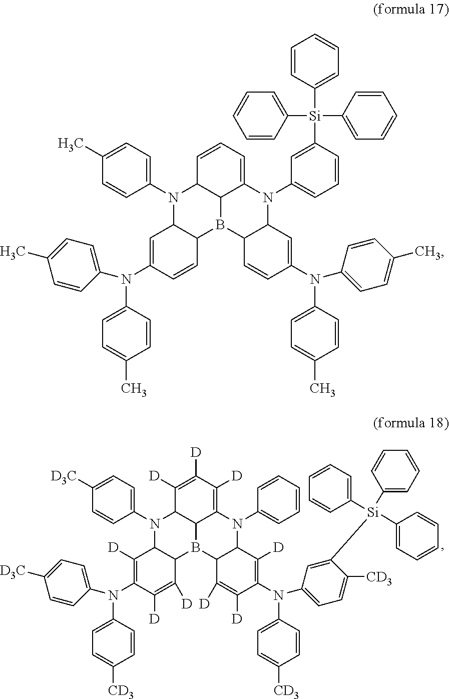 [SMILES: Cc1ccc(N(C2=CC3C(C=C2)B2C4C=CC(N(c5ccc(C)cc5)c5ccc(C)cc5)=CC4N(c4ccc(C)cc4)C4C=CC=C(C24)N3c2cccc([Si](c3ccccc3)(c3ccccc3)c3ccccc3)c2)c2ccc(C)cc2)cc1 ; [2H]C1=C([2H])C2B3C4C([2H])=C([2H])C(N(c5ccc(C([2H])([2H])[2H])cc5)c5ccc(C([2H])([2H])[2H])cc5)=C([2H])C4N(c4ccc(C([2H])([2H])[2H])cc4)C4C([2H])=C([2H])C([2H])=C(C34)N(c3ccccc3)C2C([2H])=C1N(c1ccc(C([2H])([2H])[2H])cc1)c1ccc(C([2H])([2H])[2H])c([Si](c2ccccc2)(c2ccccc2)c2ccccc2)c1]

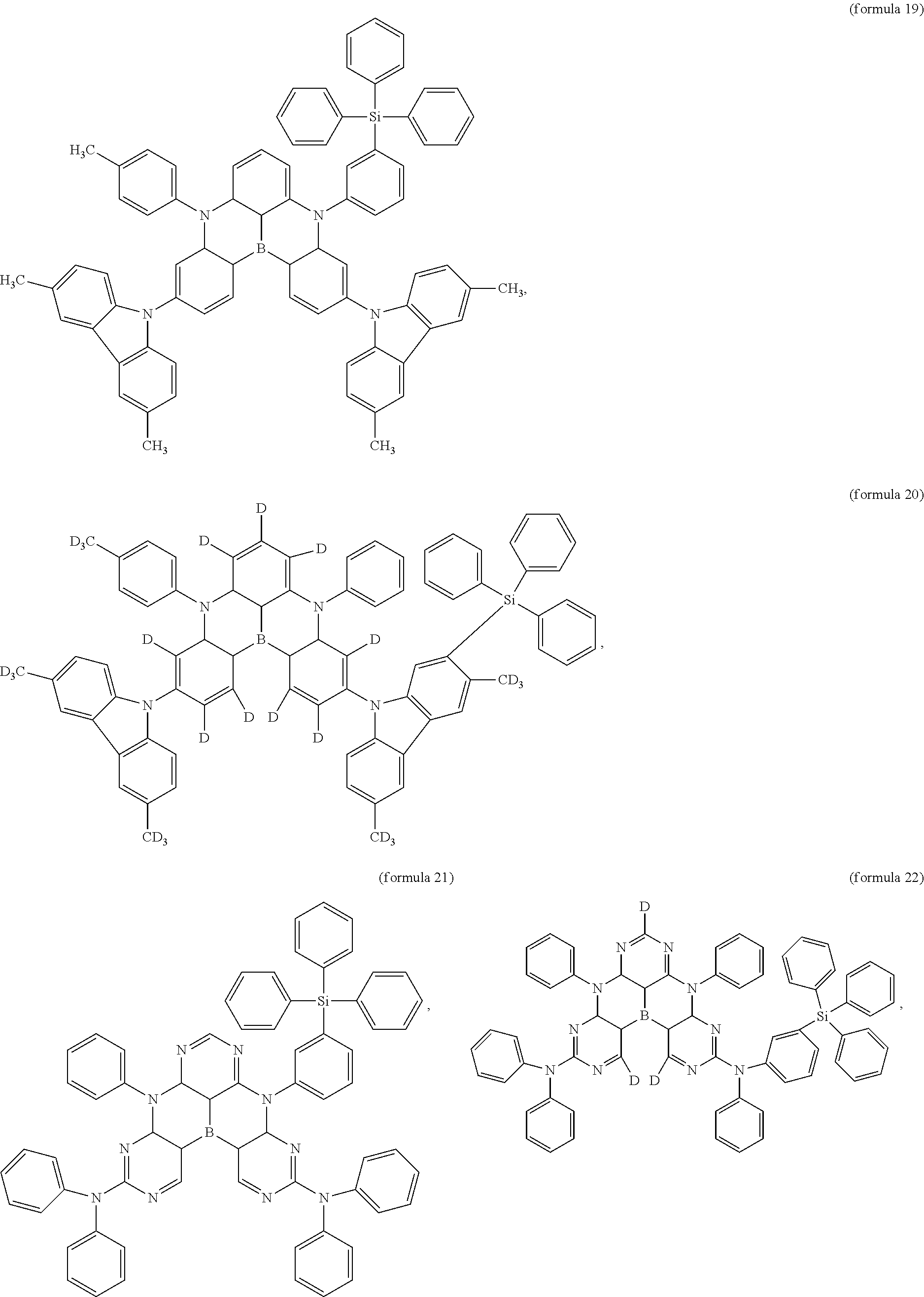

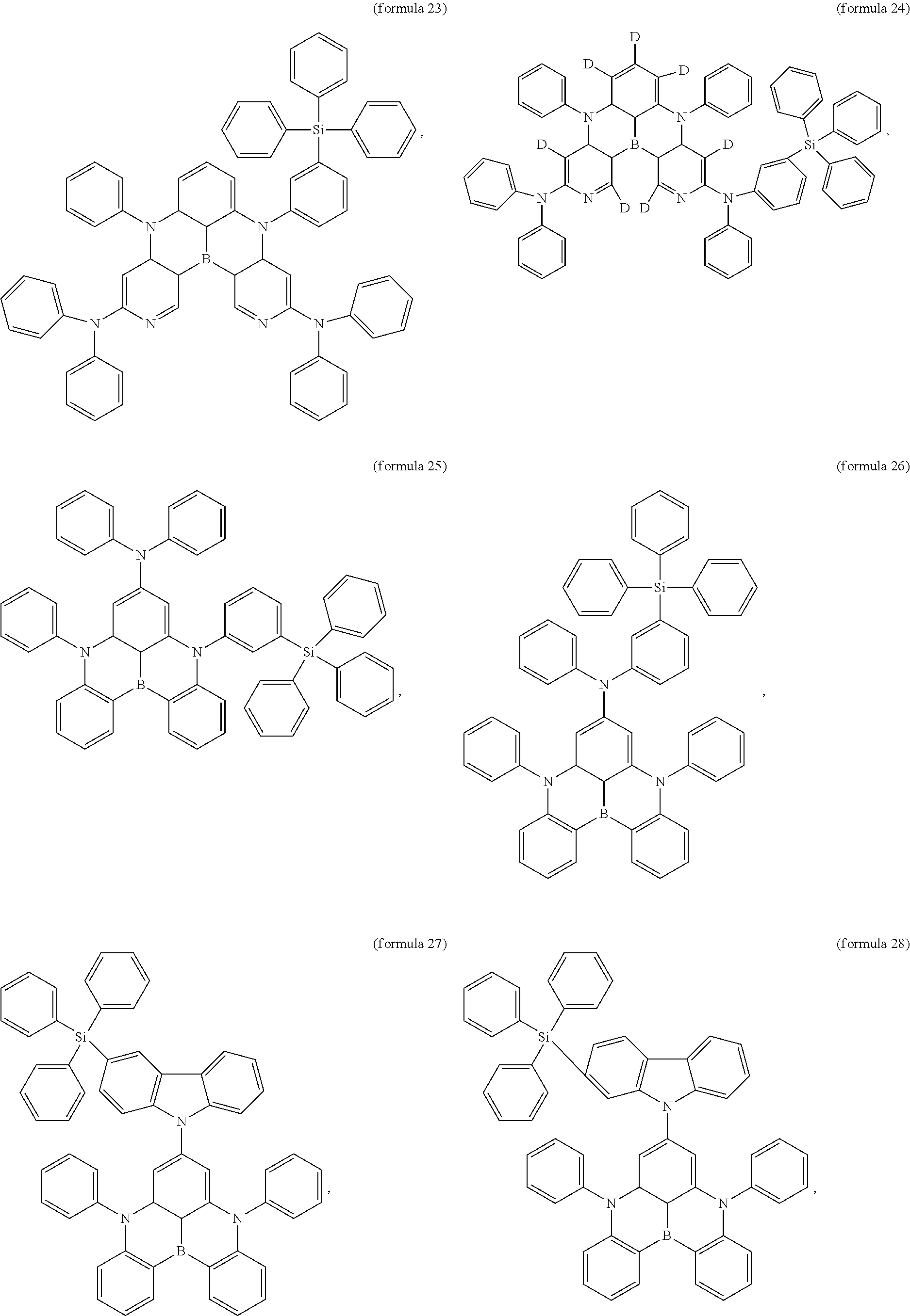

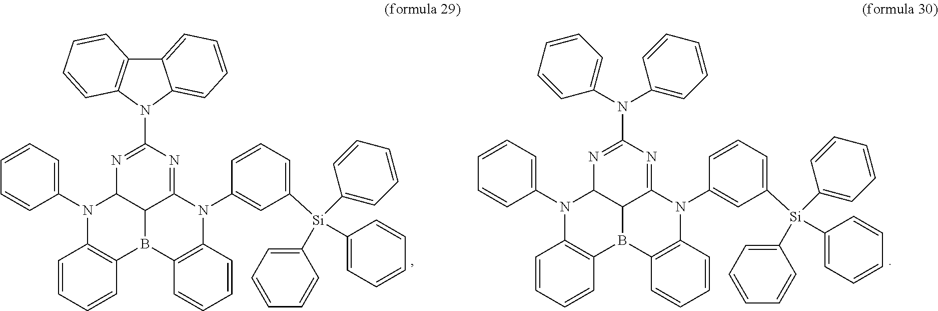 [SMILES: c1ccc(N2c3ccccc3B3c4ccccc4N(c4cccc([Si](c5ccccc5)(c5ccccc5)c5ccccc5)c4)C4=NC(n5c6ccccc6c6ccccc65)=NC2C34)cc1 ; c1ccc(N(C2=NC3C4B(c5ccccc5N(c5cccc([Si](c6ccccc6)(c6ccccc6)c6ccccc6)c5)C4=N2)c2ccccc2N3c2ccccc2)c2ccccc2)cc1]

The embodiment of the present disclosure provides an organic light-emitting diode device, wherein at least one functional layer of the organic light-emitting diode device includes the boron-nitrogen-containing organic compound in any one of the embodiments.

As an alternative, the at least one functional layer includes a luminescent layer including the boron-nitrogen-containing organic compound in any one of the embodiments.

As an alternative, the luminescent layer includes a host and the boron-nitrogen-containing organic compound, and a mass ratio of the host to the boron-nitrogen-containing organic compound is (50-90):(0-5).

As an alternative, the luminescent layer further includes a functional material as the dopant or a co-doping material, and a mass ratio of the host, the boron-nitrogen-containing organic compound and the functional material is (50-90):(0-5):(10-40).

As an alternative, the functional material is selected from compounds represented by formula 31 or formula 32:

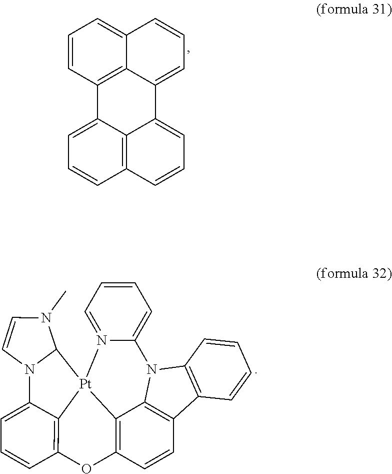

As an alternative, the organic light-emitting diode device includes an electron injection layer, an electron transport layer and/or a hole blocking layer, the luminescent layer, an electron blocking layer and/or a hole transport layer, and a hole injection layer that are sequentially stacked, where a thickness of the electron injection layer is in a range from 0 nm to 3 nm, a thickness of the electron transport layer is in a range from 20 nm to 40 nm, a thickness of the hole blocking layer is in a range from 0 nm to 10 nm, a thickness of the luminescent layer is in a range from 20 nm to 40 nm, a thickness of the electron blocking layer is in a range from 0 nm to 10 nm, a thickness of the hole transport layer is in a range from 100 nm to 200 nm, and a thickness of the hole injection layer is in a range from 0 nm to 10 nm.

The embodiment of the present disclosure provides an illumination or display apparatus, which includes the above organic light-emitting diode device.

### BRIEF DESCRIPTION OF THE DRAWINGS

In order to more clearly illustrate the technical solutions in the embodiments of the present disclosure, the drawings required to be used in the description of the embodiments are briefly introduced below. Obviously, the drawings in the description below are some embodiments of the present disclosure, and other drawings can be obtained by one of ordinary skill in the art based on these drawings without creative labor.

FIG. 1 is a schematic cross-sectional view of a structure of an organic light-emitting diode device according to an embodiment of the present disclosure;

FIG. 2 is a schematic diagram illustrating a structure of a boron-nitrogen-containing organic compound as shown in formula 3 according to an embodiment of the present disclosure;

FIG. 3 is a schematic diagram illustrating an HOMO orbital of a boron-nitrogen-containing organic compound as shown in formula 3 according to an embodiment of the present disclosure; and

FIG. 4 is a schematic diagram illustrating an LUMO orbital of a boron-nitrogen-containing organic compound as shown in formula 3 according to an embodiment of the present disclosure.

Reference numerals are as follows:
100. a cathode; 200. an electron injection layer; 300. an electron transport layer; 400. a hole blocking layer; 500. a luminescent layer; 600. an electron blocking layer; 700. a hole transport layer; 800. a hole injection layer; and 900. an anode.

### DETAIL DESCRIPTION OF THE EMBODIMENTS

The technical solutions in the embodiments of the present disclosure will be described below clearly and completely with reference to the accompanying drawings in the embodiments of the present disclosure. Obviously, the described embodiments are only some embodiments of the present disclosure, not all embodiments. All other embodiments, which can be derived by one of ordinary skill in the art from the embodiments disclosed herein without making any creative effort, shall fall within the protection scope of the present disclosure.

Moreover, reference numerals and/or reference letters may be repeated in the various examples of the present disclosure, which is for purposes of simplicity and clarity and does not dictate a relationship between the various embodiments and/or arrangements discussed. In addition, the present disclosure provides examples of various specific processes and materials, but one of ordinary skill in the art may recognize the application of other processes and/or the use of other materials.

The present disclosure is described below with reference to specific embodiments in conjunction with the drawings:

The embodiment of the present disclosure provides a boron-nitrogen-containing organic compound, the boron-nitrogen-containing organic compound has following structure in a general formula 1:

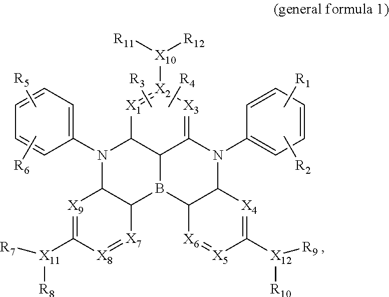

wherein at least one of R₁ to R₁₂ is a silicon-containing substituent; R₁ to R₁₂ are the same as each other or different from each other and are each independently selected from hydrogen, a substituted or unsubstituted alkyl group having 1 to 40 carbon atoms, a substituted or unsubstituted aryl group having 6 to 40 carbon atoms, a substituted or unsubstituted heteroaryl group having 5 to 60 carbon atoms, a substituted or unsubstituted fluorenyl group, a substituted or unsubstituted heterofluorenyl group, a substituted or unsubstituted aryloxy group having 6 to 60 carbon atoms, a substituted or unsubstituted alkoxy group having 1 to 39 carbon atoms, a substituted or unsubstituted arylamine group having 6 to 39 carbon atoms, a substituted or unsubstituted cycloalkyl group having 3 to 39 carbon atoms, a substituted or unsubstituted heterocycloalkyl group having 3 to 39 carbon atoms, a substituted or unsubstituted alkylsilyl group having 1 to 39 carbon atoms, a substituted or unsubstituted alkylboryl group having 1 to 39 carbon atoms, a substituted or unsubstituted arylboryl group having 6 to 39 carbon atoms, a substituted or unsubstituted arylphosphino group having 6 to 39 carbon atoms, and a substituted or unsubstituted arylsilyl group having 6 to 39 carbon atoms; R₁ and R₂ are bonded to form a ring, fused to form a ring, or do not form a ring, R₃ and R₄ are bonded to form a ring, fused to form a ring, or do not form a ring, R₅ and R₆ are bonded to form a ring, fused to form a ring, or do not form a ring, R₇ and R₅ are bonded to form a ring, fused to form a ring, or do not form a ring, R₉ and R₁₀ are bonded to form a ring, fused to form a ring, or do not form a ring, and R₁₁ and R₁₂ are bonded to form a ring, fused to form a ring, or do not form a ring; X₁ to X₁₂ are the same as each other or different from each other and are each independently selected from CH and N, at least one of X₁₀ to X₁₂ is N; the hydrogen in R₁ to R₁₂ and X₁ to X₁₂ is selected from one or more of protium, deuterium and tritium.

For the boron-nitrogen-containing organic compound provided by the embodiment of the present disclosure, by introducing the silicon-containing substituent into a molecular planar skeleton, the overlapping is avoided by the silicon-containing substituent between one dopant and another dopant and/or between a dopant and a host, the lifetime of the triplet excitons is shortened, thereby improving the luminescence efficiency of the organic light-emitting diode device and/or prolonging the lifetime of the organic light-emitting diode device. Meanwhile, the silicon-containing substituent has a small influence on the highest occupied molecular orbital (HOMO), the lowest unoccupied molecular orbital (LUMO), the triplet state (T1) and the singlet state (S1) of the boron-nitrogen-containing organic compound, and can occupy a wider space due to the fact that the silicon-carbon bond (Si—C) is longer than the carbon-carbon bond (C—C), so that the boron-nitrogen-containing organic compound has a more stereoscopic structure, and the luminescence efficiency and the lifetime of the organic light-emitting diode device are improved through the more stereoscopic structure.

TADF materials are third generation organic luminescent materials that have been developed following organic fluorescent materials and organic phosphorescent materials. TADF materials generate electrons and holes under the excitation of an electric field, the singlet excitons and the triplet excitons are generated by combination of the electrons and holes, and the excitons are attenuated by the prompt fluorescence. Such materials have a small singlet-triplet splitting energy (ΔEₛₜ), and the triplet excitons with a low energy are activated by thermal energy and are converted into the singlet excitons through the reverse intersystem crossing (RISC), thereby emitting the delayed fluorescence (TADF), which is a typical E-type TADF process. TADF materials can achieve a small singlet-triplet splitting energy (ΔEₛₜ) by spatial separation of electron cloud density distributions in the HOMO orbital and the LUMO orbital to satisfy the energy level condition for achieving effective reverse intersystem crossing (RISC).

Based on the quantum statistics principle, when the TADF is excited by the electrons, 75% of excited states are in a triplet state, and 25% of the excited states are in a singlet state. The triplet excitons emit the prompt fluorescence, while the triplet excitons may be converted into the singlet excitons through thermal activation to emit the delayed fluorescence, so that the singlet excitons and the triplet excitons formed under the excitation of the electrons can be fully utilized, and the internal quantum efficiency of the device can reach 100%.

However, when the conventional TADF material is applied to the organic light-emitting diode device as an emitter, the TADF material has a wide intrinsic reflection spectrum, for example, a half-peak width of the conventional TADF material is in a range from 80 nm to 100 nm, which results in a low color purity, so that the display requirement of the organic light-emitting diode device cannot be met.

In view of the defect that the conventional TADF material has the wide intrinsic reflection spectrum, which results in the low color purity, so that the display requirement cannot be met, boron and nitrogen atoms are introduced into the TADF material for doping, and a rigid polycyclic aromatic skeleton is constructed by combining adjacent phenyl groups to form a multiple resonance TADF (MR-TADF) material of B-N series. The nitrogen atoms and the boron atoms have opposite resonance effects, so that the electron cloud distributions in the HOMO orbital and the LUMO orbital are significantly separated from each other without introducing donor or acceptor groups. At the same time, the MR-TADF material of B-N series can achieve narrowband emission, which can significantly improve the color purity. However, in the MR-TADF material of B-N series, the dopant significantly easily overlaps with another dopant or the host and therefore, the triplet excitons of the material are relatively stable, and the lifetime of the triplet excitons is increased, which results in the reduced luminescence efficiency or the shortened lifetime of the organic light-emitting diode device. In addition, the redshift effect may occur. Therefore, the application of the TADF material of B-N series in the organic light-emitting diode device is limited.

In view of the reduced luminescence efficiency or the shortened lifetime of the TADF material of the B-N series, the present disclosure proposes an inventive concept of introducing a functional group capable of preventing intermolecular overlapping into the TADF material, that is, introducing the silicon-containing substituent into a boron-nitrogen doped molecular planar skeleton. The silicon-containing substituent has a small influence on the HOMO orbital, the LUMO orbital, the triplet state (T1) and the singlet state (S1) of the TADF material. That is, the introduction of the silicon-containing substituent has a small influence on the singlet-triplet splitting energy (ΔEₛₜ) and the narrowband emission of the TADF material, but the silicon-containing substituent can avoid the overlapping between the dopant and another dopant and between the dopant and the host, the stability of the triplet excitons is reduced, and therefore, the lifetime of the triplet excitons is shortened, and the RISC process is promoted, so that a conversion rate of the triplet excitons into the singlet excitons can be enhanced, the existence time of the excitons is shortened, and further, the luminescence efficiency is improved while the lifetime is prolonged, and the triplet excitons can further be caused to move to a short wavelength, that is, blue shift occurs, thereby implementing the TADF material for providing the deep blue light. In addition, as shown in FIG. 2, the silicon-containing substituent can occupy a wider space due to the fact that the silicon-carbon bond (Si—C) is longer than the carbon-carbon bond (C—C), so that the boron-nitrogen-containing organic compound has a more stereoscopic structure, and the luminescence efficiency and the lifetime of the organic light-emitting diode device are improved greatly through the more stereoscopic structure.

It should be noted that in the embodiments of the present disclosure, each element symbol is a general representation in the related art. A symbol “H”, unless otherwise specified, represents a hydrogen element, including three isotopes of hydrogen, that is, protium (¹H), deuterium (²H), and tritium (³H). A symbol “D” alone represents deuterium (²H).

As an alternative, in the general formula 1, R₁ to R₁₂ are independently selected from substituents containing 1 to 4 aromatic rings and/or aromatic heterocyclic rings.

In the organic light-emitting diode device, in order to increase the external quantum efficiency (EQE) of the organic light-emitting diode device, in addition to careful design of the structure and electrical performance of the device, the efficiency is directly dependent on the intrinsic efficiency of the luminescent material used, i.e., a ratio for photons emitted per molecule upon excitation. This efficiency is usually quantified in photoluminescence (PL) experiments, the so-called photoluminescence quantum yield (PLQY).

In some embodiments, by introducing the aromatic ring and/or the aromatic heterocyclic ring into the skeleton of the boron-nitrogen-containing organic compound shown in the general formula 1, the dispersion of the HOMO orbital on a molecular orbital can be expanded to a certain extent, so that the photoluminescence quantum yield (PLQY) of the boron-nitrogen-containing organic compound can be improved, and further the external quantum efficiency (EQE) of the organic light-emitting diode device can be improved. The introduction of 1 to 4 aromatic rings and/or aromatic heterocyclic rings can improve the stereoscopic of the whole boron-nitrogen-containing organic compound, so that the structure of the boron-nitrogen-containing organic compound is more stereoscopic, and the luminescence efficiency and the lifetime of the organic light-emitting diode device are improved.

As an alternative, in the general formula 1, R₁ and R₂ are bonded to form a 5 to 8-membered ring, and/or R₃ and R₄ are bonded to form a 5 to 8-membered ring, and/or R₅ and R₆ are bonded to form a 5 to 8-membered ring, and/or R₇ and R₅ are bonded to form a 5 to 8-membered ring, and/or R₉ and R₁₀ are bonded to form a 5 to 8-membered ring, and/or R₁₁ and R₁₂ are bonded to form a 5 to 8-membered ring.

In some embodiments, R₁ and R₂ are bonded to form a 5 to 8-membered ring, and/or R₃ and R₄ are bonded to form a 5 to 8-membered ring, and/or R₅ and R₆ are bonded to form a 5 to 8-membered ring, and/or R₇ and R₅ are bonded to form a 5 to 8-membered ring, and/or R₉ and R₁₀ are bonded to form a 5 to 8-membered ring, and/or R₁₁ and R₁₂ are bonded to form a 5 to 8-membered ring, which can stabilize the structure and relative position of the adjacent substituents, and can also stabilize an torsion angle between the adjacent substituents and the skeleton of the boron-nitrogen-containing organic compound to a certain extent, thereby avoiding the change of the torsion angle between the adjacent substituents and the skeleton, and further, the instability of the boron-nitrogen-containing organic compound caused by the change of the torsion angle can be avoided, and the performance attenuation of the organic light-emitting diode device caused by the instability of the boron-nitrogen-containing organic compound is avoided. That is, the adjacent substituents are bonded to form a 5 to 8-membered ring, so that the efficiency of the organic light-emitting diode device can be improved to a certain extent, the lifetime of the organic light-emitting diode device can be prolonged, and the defects of efficiency roll-off and shortened lifetime of the organic light-emitting diode device can be avoided.

As an alternative, in the general formula 1, X₁, X₃, X₄, X₅, X₈, X₉, X₁₀, X₁₁ and X₁₂ are the same as each other or different from each other, and are independently selected from CD and N.

As an alternative, in the general formula 1, X₂, X₆, and X₇ are the same as each other or different from each other, and are independently selected from CD and N.

In some embodiments of the present disclosure, in the boron-nitrogen-containing organic compound represented by the general formula 1, since the phenyl group of the skeleton is connected with the electron-withdrawing functional group boron (B), the chemical reactivity in the meta position of the electron-withdrawing functional group boron (B) in the phenyl group will be enhanced, and the chemical reactivity in the ortho and para positions of the electron-withdrawing functional group boron (B) in the phenyl group will be enhanced to some extent.

Since the phenyl group of the skeleton is also connected with an electron-donating functional group nitrogen (N), the meta position of the electron-withdrawing functional group boron (B) and the ortho position of the electron-donating functional group nitrogen (N) are in the same position of the phenyl group of the skeleton, that is, sites shown by X₁, X₃, X₄, X₅, X₈, X₉, X₁₀, X₁₁ and X₁₂ in the general formula 1, the chemical reaction activity of the sites of the phenyl group becomes very high, so that hydrogen in the sites of the phenyl group is easy to drop off, the stability of the boron-nitrogen-containing organic compound is reduced, and the lifetime of the organic light-emitting diode device is further reduced. In order to avoid the reduction of the lifetime of the organic light-emitting diode device due to this reason, in some embodiments, CH groups at the sites indicated by X₁, X₃, X₄, X₅, X₈, X₉, X₁₀, X₁₁ and X₁₂ in the phenyl group of the skeleton may be replaced with CD groups and/or N groups, that is, protium (H) at these sites of the phenyl group of the skeleton may be replaced with deuterium (D), or CH at these sites may be directly replaced with nitrogen (N), so that the activities of these sites may be reduced, and the protium (H) on the phenyl group may be prevented from dropping off, to improve the stability of the boron-nitrogen-containing organic compound according to the embodiment of the present disclosure, and thus to improve the lifetime of the organic light-emitting diode device.

In addition, because the ortho position and para positions of the electron-withdrawing functional group boron (B) in the phenyl group of the skeleton and the meta position of the electron-donating functional group nitrogen (N) are located at the same positions of the phenyl group of the skeleton, that is, the sites indicated by X₂, X₆, and X₇ in the general formula 1, the chemical reaction activity of the sites is also increased to a certain extent, so that hydrogen in the sites of the phenyl group is easy to drop off, the stability of the boron-nitrogen-containing organic compound is reduced, and the lifetime of the organic light-emitting diode device is further shortened. In order to avoid the reduction of the lifetime of the organic light-emitting diode device due to this reason, in some embodiments, CH groups at the sites indicated by X₂, X₆, and X₇ in the phenyl group of the skeleton may be replaced with CD groups and/or N groups, that is, protium (H) at the sites of the phenyl group of the skeleton may be replaced with deuterium (D), or CH at the sites may be directly replaced with nitrogen (N), so that the activities of the sites may be reduced, and the protium (H) on the phenyl group may be prevented from dropping off, to improve the stability of the boron-nitrogen-containing organic compound according to the embodiment of the present disclosure, and thus to improve the lifetime of the organic light-emitting diode device. As an alternative, the boron-nitrogen-containing organic compound has following structure in a general formula 2 or 3:

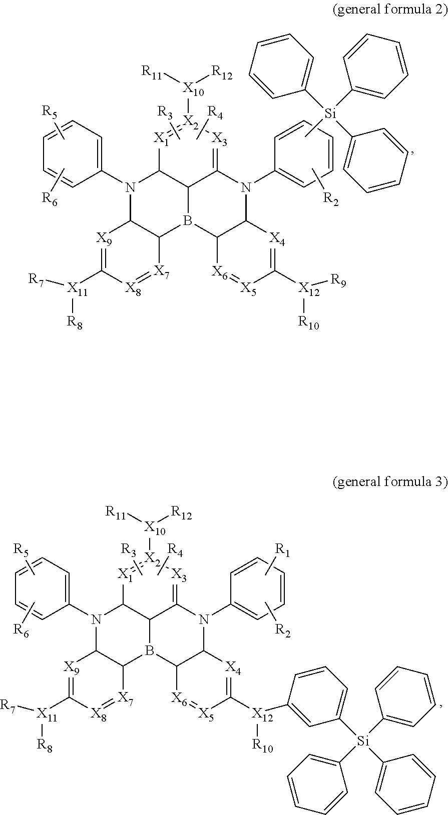

in the general formulas 2 and 3, the definitions of R₁ to R₁₂ and X₁ to X₁₂ are the same as those in the general formula 1.

In some embodiments, a silicon-containing substituent as shown in the general formula 2 or 3 may be introduced into the boron-nitrogen-containing organic compound shown in the general formula 1, and the silicon-containing substituent is connected with a plurality of phenyl groups. As shown in FIG. 2, the plurality of phenyl groups connected with silicon are twisted with respect to each other, so that the structure of the silicon-containing substituent itself is more stereoscopic. When the substituent is connected with a planar molecular skeleton, the phenyl groups in the silicon-containing substituent and the molecular skeleton are not in the same plane, so that the molecular structure of the formed boron-nitrogen-containing organic compound is more stereoscopic, and therefore, the overlapping between dopants and the overlapping between a dopant and a host are avoided to some extent, the stability of the triplet excitons is reduced, and therefore, the lifetime of the triplet excitons is shortened, and the RISC process is promoted, a conversion rate of the triplet excitons into the singlet excitons can be enhanced, the existence time of the excitons is shortened, and further, the luminescence efficiency is improved while the lifetime is prolonged, and the triplet excitons can further be caused to move to a short wavelength, that is, blue shift occurs, thereby implementing the TADF material for providing the deep blue light.

Since the silicon-carbon bond (Si—C) is longer than the carbon-carbon bond (C—C), the space occupied by the silicon-containing substituent formed by connecting silicon and the plurality of phenyl groups is larger, the stereoscopic of the structure is stronger, and the structure of the boron-nitrogen-containing organic compound can be more stereoscopic, so that the capability of avoiding the overlapping between dopants and the overlapping between a dopant and a host can be improved, and the organic light-emitting diode device has higher luminescence efficiency and longer lifetime.

As an alternative, the singlet (E_{S1})-triplet (E_{T1}) splitting energy (ΔEₛₜ) of the boron-nitrogen-containing organic compound is greater than 0 eV and less than 1.0 eV.

In the TADF material, the splitting energy (ΔEₛₜ) is one of the most important physical parameters of the TADF material, and the smaller splitting energy (ΔEₛₜ) is a main characteristic of the TADF material, which largely affects the reverse intersystem crossing (RISC) process, and the smaller the splitting energy (ΔEₛₜ) is, the easier the triplet excitons realize the reverse intersystem crossing (RISC) process. That is, the splitting energy (ΔEₛₜ) is inversely related to a rate of reverse intersystem crossing (RISC) process of triplet excitons, and the smaller splitting energy (ΔEₛₜ) may increase the conversion efficiency of the triplet excitons to the singlet excitons, which in turn may be beneficial for increasing the external quantum efficiency (EQE) of the TADF material.

In some embodiments of the present disclosure, the singlet (E_{S1})-triplet (E_{T1}) splitting energy (ΔEₛₜ) of the boron-nitrogen-containing organic compound may be greater than 0 eV and less than 1.0 eV, that is, the splitting energy (ΔEₛₜ) is as close to 0 eV as possible, so that the triplet excitons are more easily converted into the singlet excitons, thereby improving the luminescence efficiency of the organic light-emitting diode device and prolonging the lifetime of the organic light-emitting diode device.

In some embodiments, the splitting energy (ΔEₛₜ) is calculated based on time-dependent density functional theory (TD-DFT), and the simulation calculation is performed on the B3LYP/6-31G (d, p) basis level in the time-dependent density functional theory.

As an alternative, the boron-nitrogen-containing organic compound satisfies the following condition: a triplet energy level (E_{T1}) is greater than or equal to 2.60 eV; a triplet excitation wavelength (λ_{T1}) is less than or equal to 480 nm; and a HOMO orbital energy level (E_{HOMO}) is greater than or equal to 4.60 eV.

In some embodiments, as for the boron-nitrogen-containing organic compound, the triplet energy level (E_{T1}) is greater than or equal to 2.60 eV and the HOMO orbital energy level (E_{HOMO}) is greater than or equal to 4.60 eV, so that on one hand, the small singlet (E_{S1})-triplet (E_{T1}) splitting energy (ΔEₛₜ) can be ensured, and on the other hand, the triplet excitation wavelength (λ_{T1}) is shortened to 480 nm or less, to emit deeper blue light and reduce the full width at half maxima (FWHM), which results in higher purity of the emitted blue light. In addition, the stability of the boron-nitrogen-containing organic compound can be improved, the luminescence efficiency of the organic light-emitting diode device can be improved, and a driving voltage of the organic light-emitting diode device can be reduced.

As an alternative, the boron-nitrogen-containing organic compound is represented by any one of formulas 1 to 30:

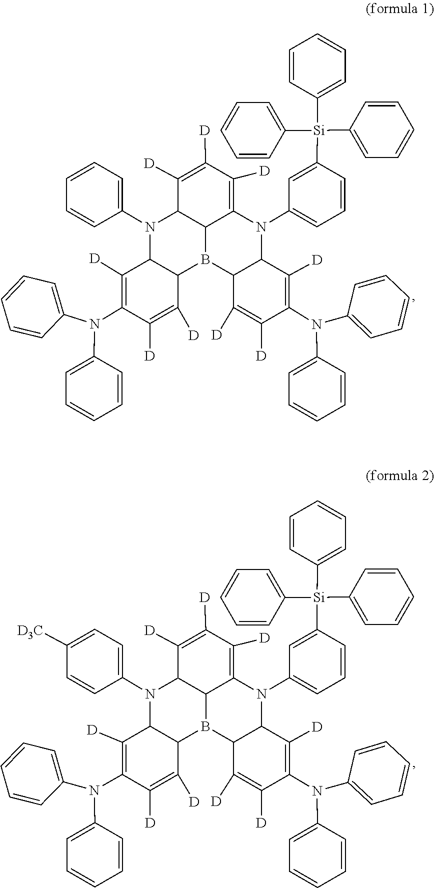 [SMILES: [2H]C1=C([2H])C2B3C4C([2H])=C([2H])C(N(c5ccccc5)c5ccccc5)=C([2H])C4N(c4ccccc4)C4C([2H])=C([2H])C([2H])=C(C34)N(c3cccc([Si](c4ccccc4)(c4ccccc4)c4ccccc4)c3)C2C([2H])=C1N(c1ccccc1)c1ccccc1 ; [2H]C1=C([2H])C2B3C4C([2H])=C([2H])C(N(c5ccccc5)c5ccccc5)=C([2H])C4N(c4ccc(C([2H])([2H])[2H])cc4)C4C([2H])=C([2H])C([2H])=C(C34)N(c3cccc([Si](c4ccccc4)(c4ccccc4)c4ccccc4)c3)C2C([2H])=C1N(c1ccccc1)c1ccccc1]

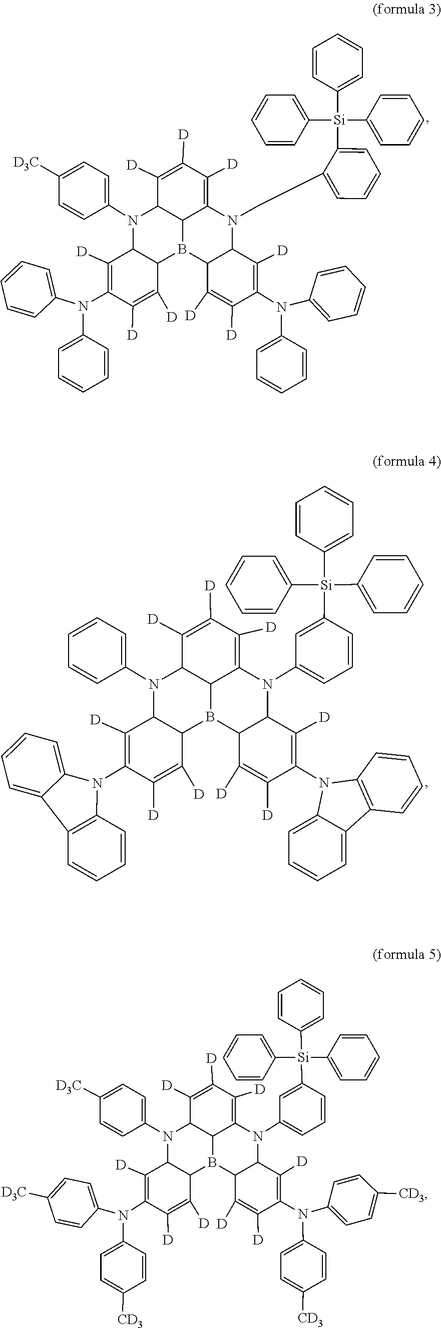

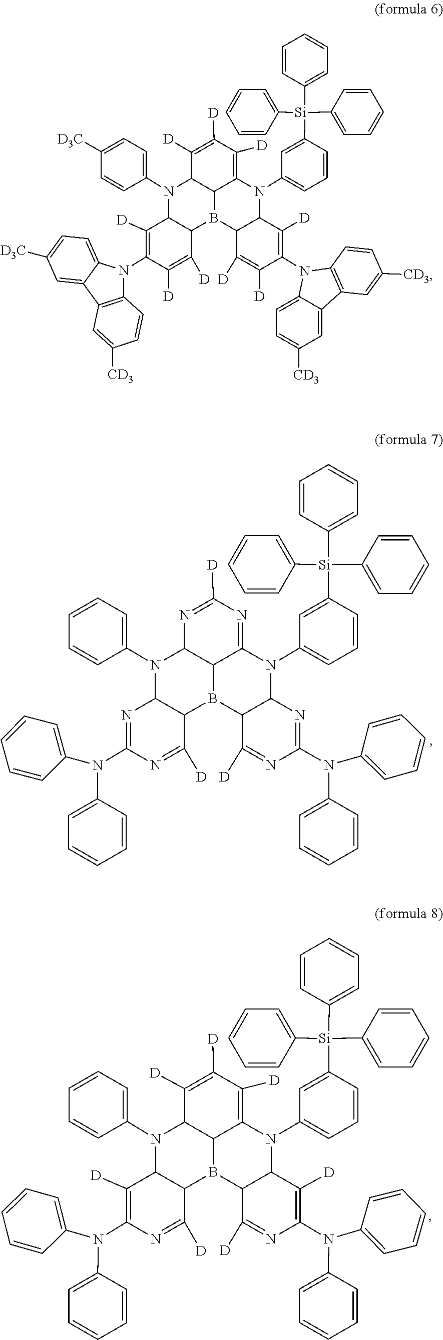

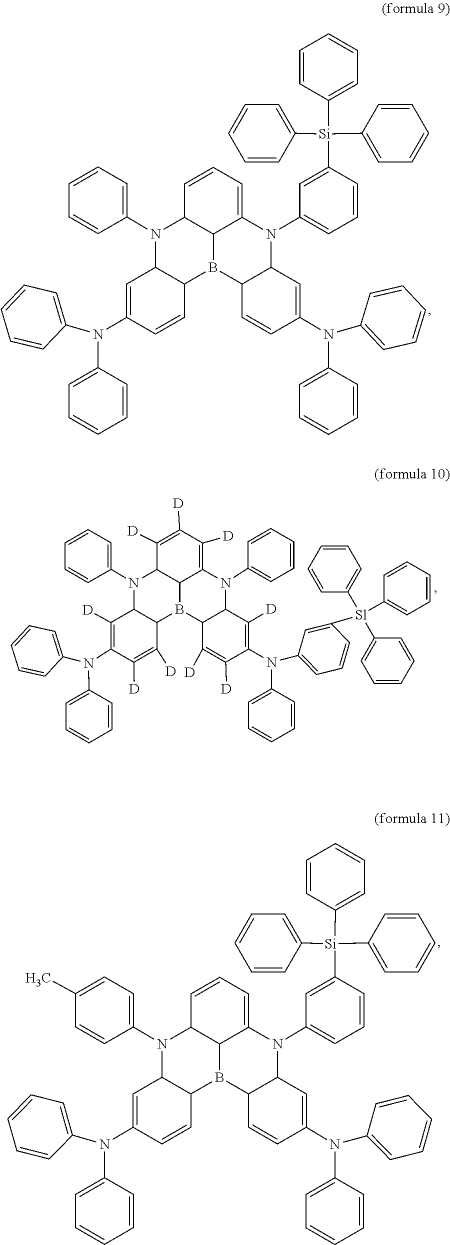

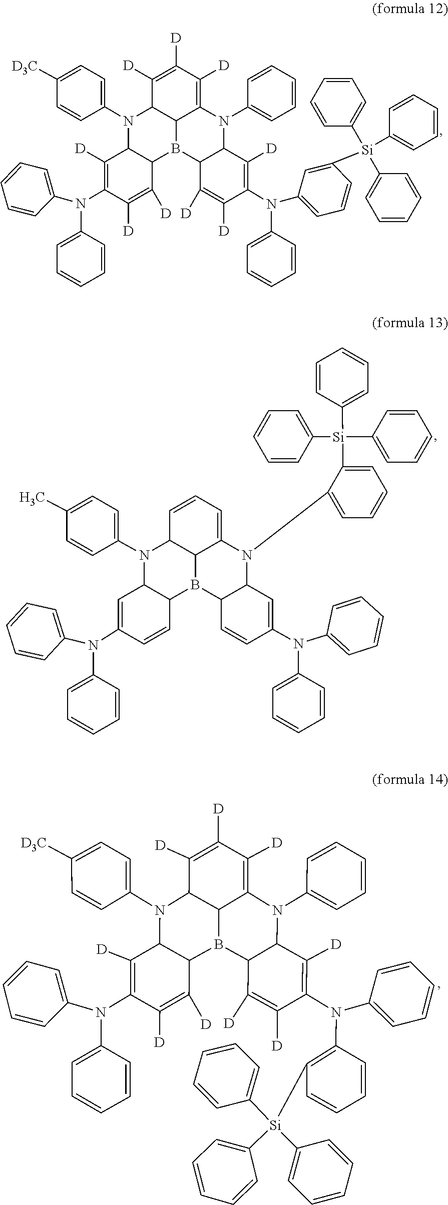

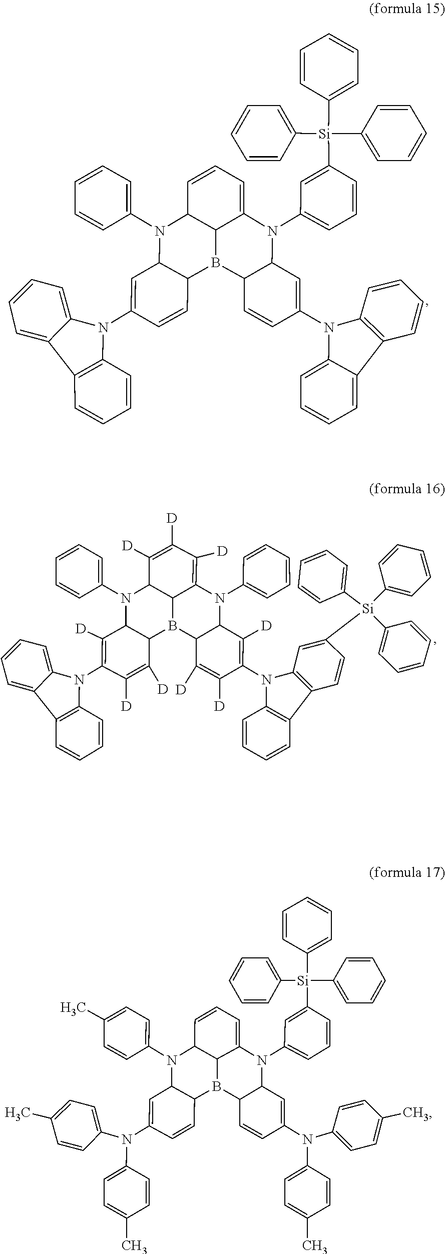 [SMILES: C1=CC2C3B(C4C=CC(n5c6ccccc6c6ccccc65)=CC4N(c4cccc([Si](c5ccccc5)(c5ccccc5)c5ccccc5)c4)C3=C1)C1C=CC(n3c4ccccc4c4ccccc43)=CC1N2c1ccccc1 ; [2H]C1=C([2H])C2B3C4C([2H])=C([2H])C(n5c6ccccc6c6ccccc65)=C([2H])C4N(c4ccccc4)C4C([2H])=C([2H])C([2H])=C(C34)N(c3ccccc3)C2C([2H])=C1n1c2ccccc2c2ccc([Si](c3ccccc3)(c3ccccc3)c3ccccc3)cc21 ; Cc1ccc(N(C2=CC3C(C=C2)B2C4C=CC(N(c5ccc(C)cc5)c5ccc(C)cc5)=CC4N(c4ccc(C)cc4)C4C=CC=C(C24)N3c2cccc([Si](c3ccccc3)(c3ccccc3)c3ccccc3)c2)c2ccc(C)cc2)cc1]

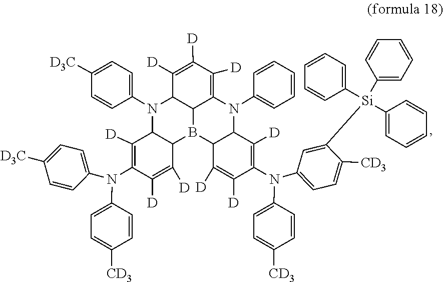 [SMILES: [2H]C1=C([2H])C2B3C4C([2H])=C([2H])C(N(c5ccc(C([2H])([2H])[2H])cc5)c5ccc(C([2H])([2H])[2H])cc5)=C([2H])C4N(c4ccc(C([2H])([2H])[2H])cc4)C4C([2H])=C([2H])C([2H])=C(C34)N(c3ccccc3)C2C([2H])=C1N(c1ccc(C([2H])([2H])[2H])cc1)c1ccc(C([2H])([2H])[2H])c([Si](c2ccccc2)(c2ccccc2)c2ccccc2)c1]

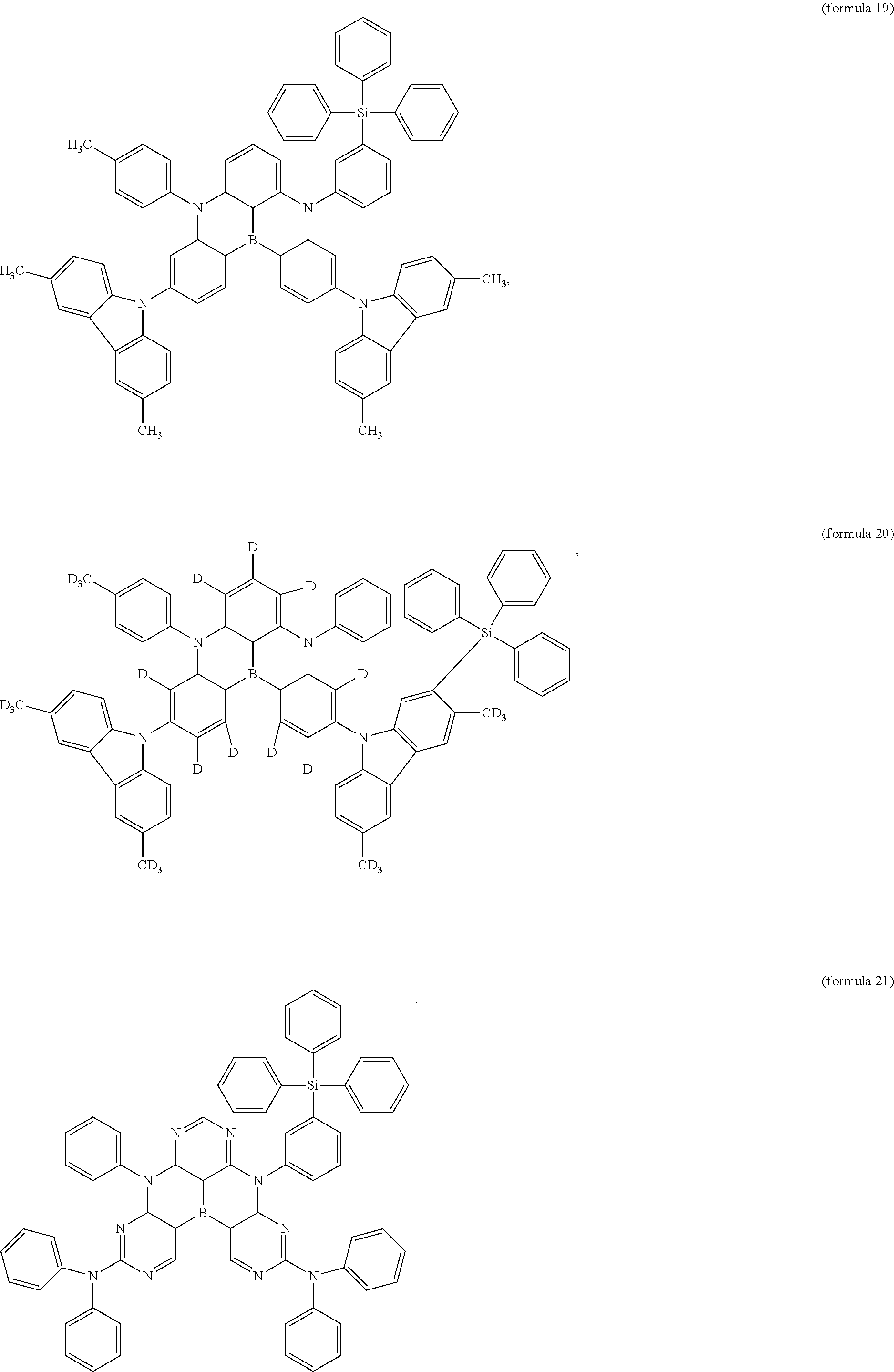

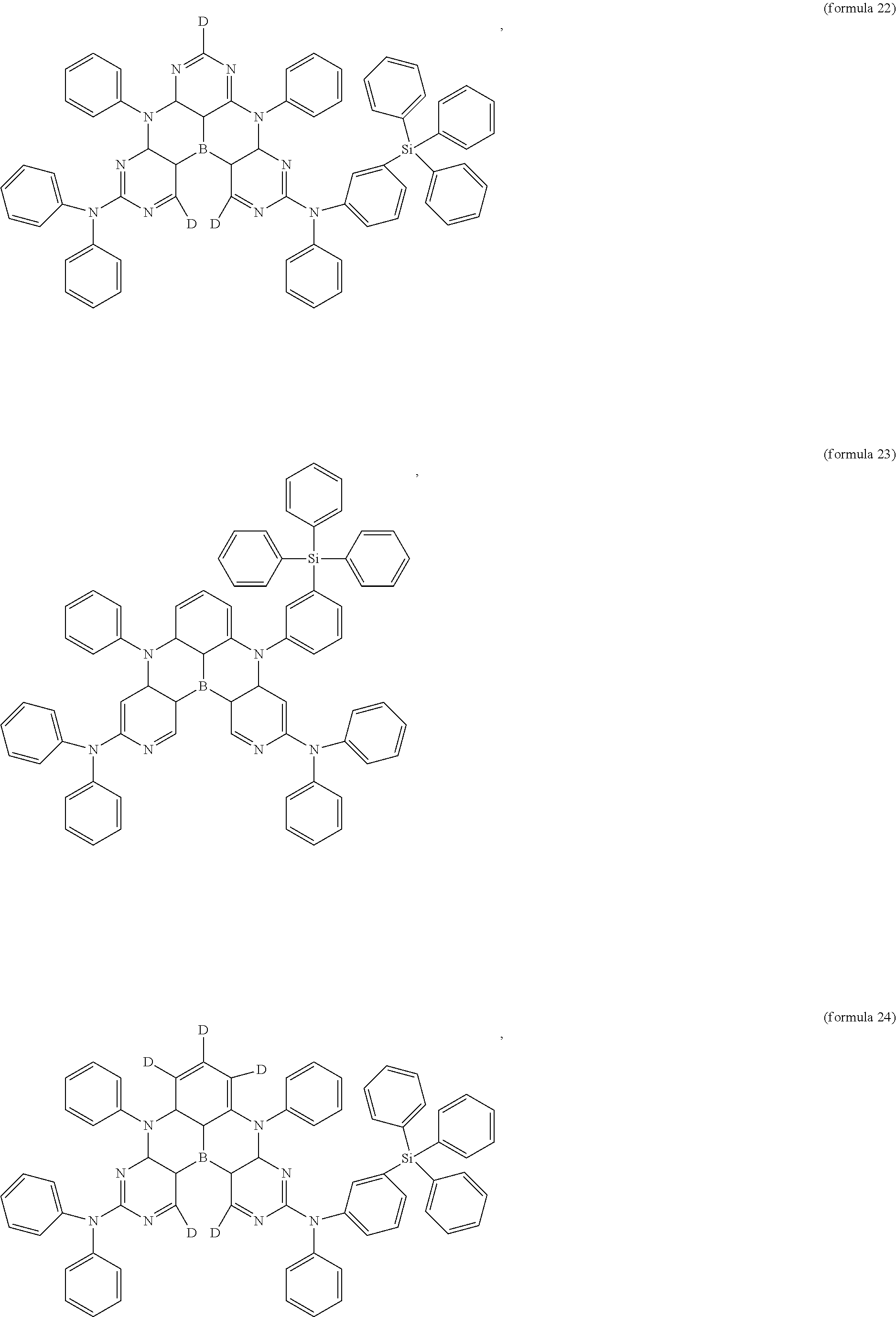 [SMILES: [2H]C1=NC2C3B(C4C([2H])=NC(N(c5ccccc5)c5cccc([Si](c6ccccc6)(c6ccccc6)c6ccccc6)c5)=NC4N(c4ccccc4)C3=N1)C1C([2H])=NC(N(c3ccccc3)c3ccccc3)=NC1N2c1ccccc1 ; C1=CC2C3B(C4C=NC(N(c5ccccc5)c5ccccc5)=CC4N(c4cccc([Si](c5ccccc5)(c5ccccc5)c5ccccc5)c4)C3=C1)C1C=NC(N(c3ccccc3)c3ccccc3)=CC1N2c1ccccc1 ; [2H]C1=NC(N(c2ccccc2)c2cccc([Si](c3ccccc3)(c3ccccc3)c3ccccc3)c2)=NC2C1B1C3C([2H])=NC(N(c4ccccc4)c4ccccc4)=NC3N(c3ccccc3)C3C([2H])=C([2H])C([2H])=C(C13)N2c1ccccc1]

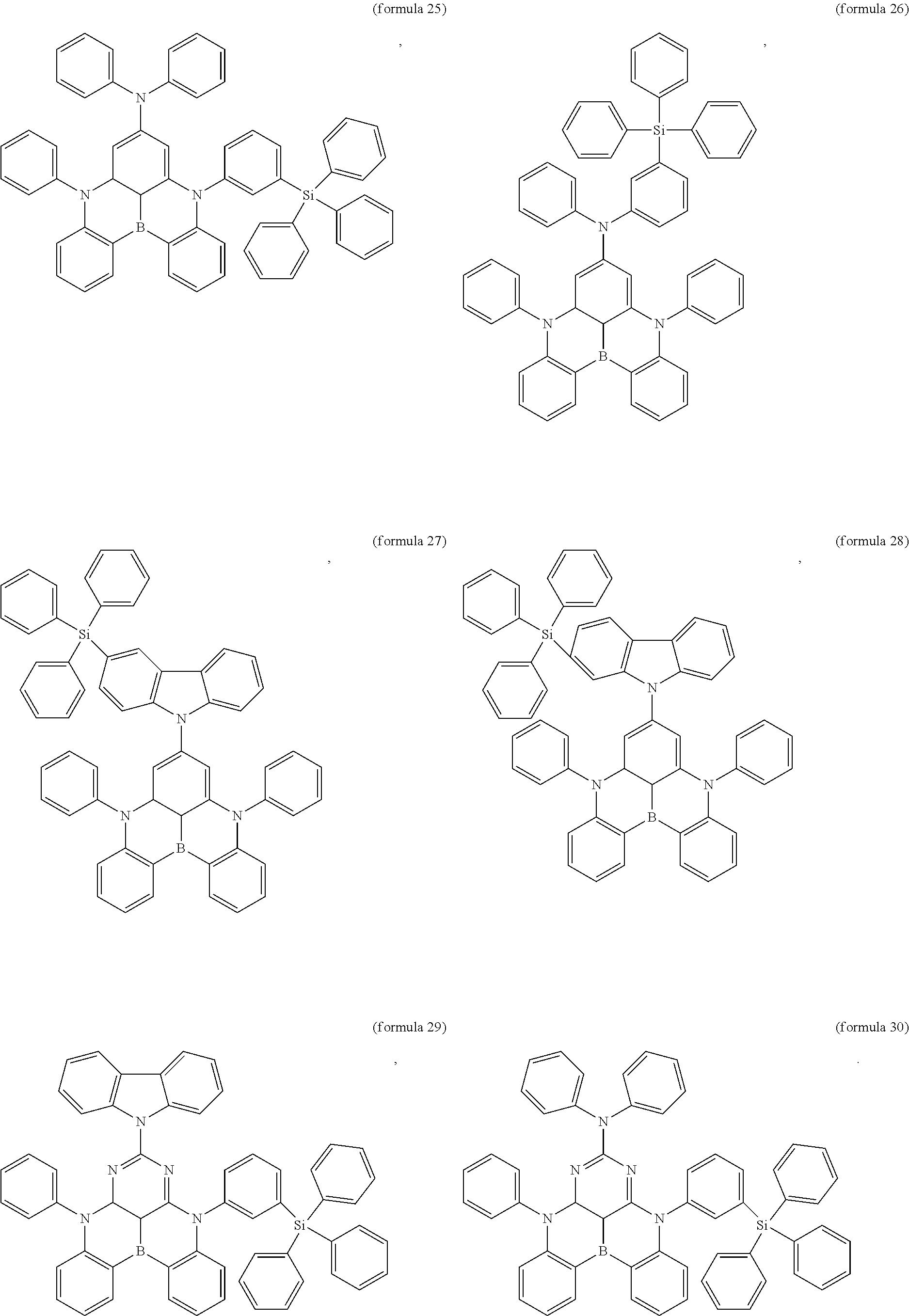

Based on the time-dependent density functional theory (TD-DFT), the simulation calculation is performed on the B3LYP/6-31G (d, p) basis level for the boron-nitrogen-containing organic compound in the above embodiment, and performance parameters such as the triplet energy level and the like of the boron-nitrogen-containing organic compound in the above embodiment are obtained through simulation calculation, and the structure is shown in table 1.

TABLE 1
Performance parameters of the boron-nitrogen-containing organic compound

| | Triplet | Triplet | HOMO | LUMO | Singlet | Singlet |
|---|---|---|---|---|---|---|
| | excitation | level | orbital level | orbital level | excitation | level |
| | wavelength | (E_{T1}) | (E_{HOMO}) | (E_{LUMO}) | wavelength | (E_{S1}) |
| Material | (λ_{T1})(nm) | (eV) | (eV) | (eV) | (λ_{S1}) (nm) | (eV) |
| Formula 1 | 477 | 2.60 | 4.60 | 1.07 | 412 | 3.01 |
| Formula 2 | 478 | 2.59 | 4.59 | 1.06 | 413 | 3.00 |
| Formula 3 | 475 | 2.61 | 4.59 | 1.05 | 411 | 3.02 |
| Formula 4 | 479 | 2.59 | 4.98 | 1.42 | 410 | 3.02 |
| Formula 5 | 478 | 2.59 | 4.49 | 0.98 | 414 | 2.99 |
| Formula 6 | 478 | 2.59 | 4.93 | 1.38 | 411 | 3.02 |
| Formula 7 | 438 | 2.83 | 5.37 | 1.68 | 388 | 3.20 |
| Formula 8 | 443 | 2.80 | 4.91 | 1.20 | 386 | 3.21 |
| Formula 10 | 477 | 2.60 | 4.62 | 1.09 | 412 | 3.01 |
| Formula 12 | 477 | 2.60 | 4.60 | 1.07 | 412 | 3.01 |
| Formula 14 | 475 | 2.61 | 4.61 | 1.07 | 411 | 3.02 |
| Formula 16 | 478 | 2.59 | 5.00 | 1.44 | 410 | 3.02 |
| Formula 18 | 477 | 2.60 | 4.50 | 0.98 | 413 | 3.00 |
| Formula 20 | 477 | 2.60 | 4.90 | 1.35 | 411 | 3.02 |
| Formula 22 | 437 | 2.84 | 5.38 | 1.67 | 386 | 3.21 |
| Formula 24 | 442 | 2.80 | 4.91 | 1.20 | 387 | 3.20 |
| Formula 25 | 466 | 2.66 | 4.82 | 1.15 | 395 | 3.14 |
| Formula 26 | 463 | 2.68 | 4.75 | 1.07 | 394 | 3.14 |
| Formula 27 | 464 | 2.67 | 4.99 | 1.29 | 390 | 3.18 |
| Formula 28 | 468 | 2.65 | 4.94 | 1.26 | 392 | 3.16 |
| Formula 29 | 397 | 3.12 | 5.40 | 1.41 | 349 | 3.55 |
| Formula 30 | 388 | 3.19 | 5.43 | 1.18 | 341 | 3.64 |

Synthetic routes may be designed and compounds may be prepared for the boron-nitrogen-containing organic compound in the above embodiments by using conventional methods, and the present disclosure further exemplarily provides some synthetic routes and preparation method of the boron-nitrogen-containing organic compound. It should be noted that the preparation method of the boron-nitrogen-containing organic compound below is not used to limit the characteristics of the heterocyclic ring compound.

For example, in some embodiments, the boron-nitrogen-containing organic compound shown in the formula 3 may adopt the following synthetic route as shown in equation 1.

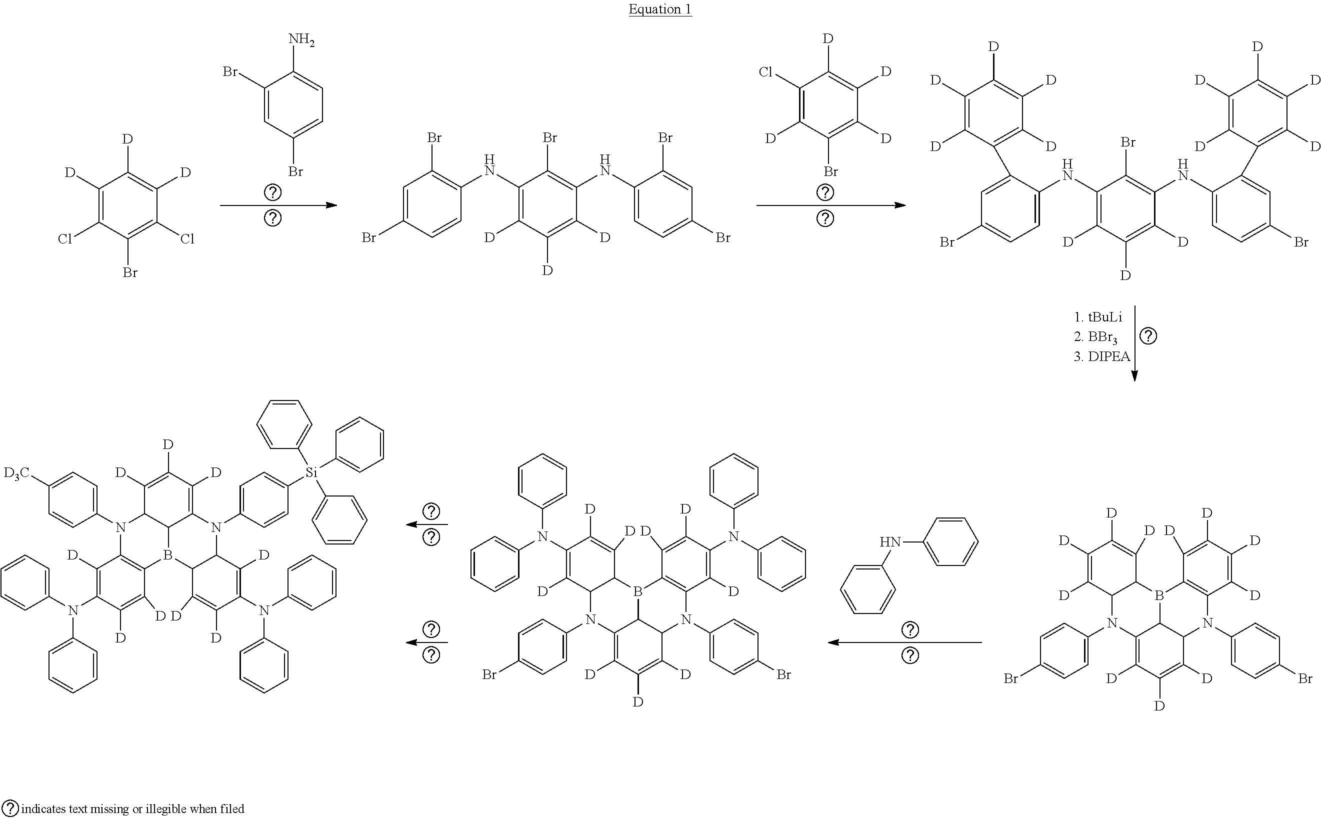

Based on the same inventive concept, the present disclosure further provides an organic light-emitting diode device, and at least one functional layer of the organic light-emitting diode device contains the boron-nitrogen-containing organic compound.

The organic light-emitting diode device provided by the embodiment of the present disclosure includes the boron-nitrogen-containing organic compound, so that the organic light-emitting diode device may emit blue light with higher purity, the stability of the organic light-emitting diode device is improved, the organic light-emitting diode device has higher luminescence efficiency and longer lifetime, the defects of serious efficiency roll-off and short lifetime of the TADF material for the blue light in the related art are overcome to a certain extent, and the boron-nitrogen-containing organic compound as the TADF material can be better commercially applied.

In some embodiments of the present disclosure, the boron-nitrogen-containing organic compound may be used in a blue organic light-emitting diode device, a red organic light-emitting diode device, or a green organic light-emitting diode device. The boron-nitrogen-containing organic compound may be used in a single-layer organic light-emitting diode device or a multi-layer organic light-emitting diode device.

In some embodiments, the organic light-emitting diode device includes an anode, a cathode, and at least one functional layer between the anode and the cathode, wherein the at least one functional layer of the organic light-emitting diode device contains the boron-nitrogen-containing organic compound described above.

As an alternative, the functional layer includes a luminescent layer (EML) containing the boron-nitrogen-containing organic compound in at least one of the above embodiments.

In some embodiments of the present disclosure, the boron-nitrogen-containing organic compound may serve as a host, a dopant, or a co-doping material of the luminescent layer. The host may also be referred to as a matrix material; the dopant refers to a material for emitting light in the luminescent layer, and may also be referred to as a luminescent material; and the co-doping material refers to a material which emits light with an auxiliary doped material in the luminescent layer, and may be also referred to as a sensitizing material.

As an alternative, the luminescent layer includes a host and the boron-nitrogen-containing organic compound, and a mass ratio of the host to the boron-nitrogen-containing organic compound is (50-90):(0-5). The boron-nitrogen-containing organic compound may be used as the dopant or the co-doping material.

In some embodiments, the luminescent layer may include a host and the boron-nitrogen-containing organic compound as the dopant (the luminescent material).

In some embodiments, the luminescent layer may include a host and the boron-nitrogen-containing organic compound as the co-doping material (the sensitizing material), and in this case, the luminescent layer may necessarily include other dopants (other luminescent materials) together.

As an alternative, the luminescent layer further includes a functional material as the dopant (the luminescent material) or the co-doping material (the sensitizing material), and a mass ratio of the host, the boron-nitrogen-containing organic compound and the functional material is (50-90):(0-5):(10-40).

In some embodiments, the luminescent layer includes the host, the boron-nitrogen-containing organic compound, and the functional material. When the boron-nitrogen-containing organic compound is used as the dopant (the luminescent material), the functional material is used as the co-doping material (the sensitizing material); when the boron-nitrogen-containing organic compound is used as the co-doping material (the sensitizing material), the functional material is used as the dopant (the luminescent material). That is, the luminescent layer may include the host, the dopant, and the co-doping material. The boron-nitrogen-containing organic compound provided in the embodiment of the present disclosure may serve as the dopant (the luminescent material) collocated with the functional material as the co-doping material (the sensitizing material), or the boron-nitrogen-containing organic compound provided in the embodiment of the present disclosure may also serve as the co-doping material (the sensitizing material) collocated with the functional material as the dopant (the luminescent material).

In some embodiments, the luminescent layer may include the host, the boron-nitrogen-containing organic compound as the dopant, and a fluorescent compound as the co-doping material.

In some embodiments, the luminescent layer may include the host, a fluorescent compound as the dopant, and the boron-nitrogen-containing organic compound as the co-doping material.

In some embodiments, the luminescent layer may include the host, the boron-nitrogen-containing organic compound as the dopant, and a phosphorescent compound as the co-doping material.

In some embodiments, the luminescent layer may include the host, a phosphorescent compound as the dopant, and the boron-nitrogen-containing organic compound as the co-doping material.

As an alternative, the functional material is selected from compounds represented by formula 31 or formula 32:

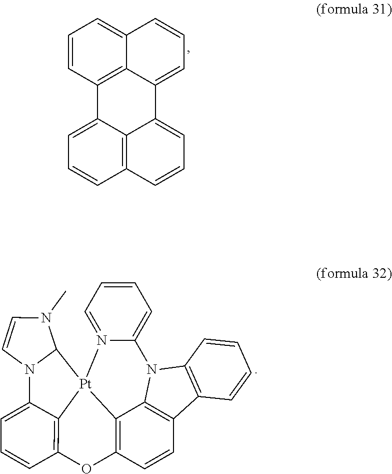

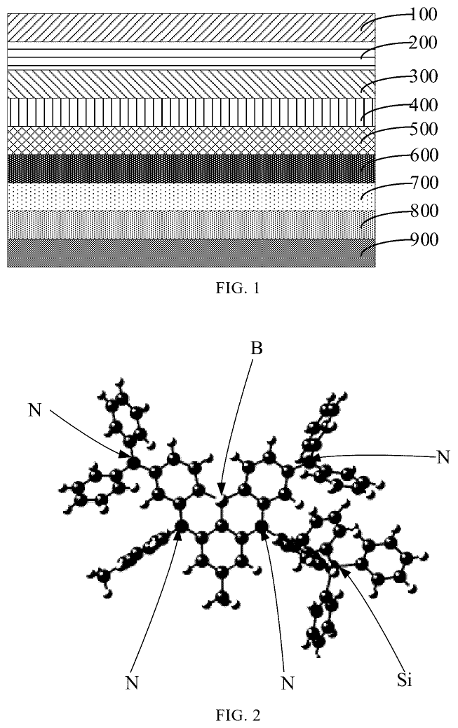

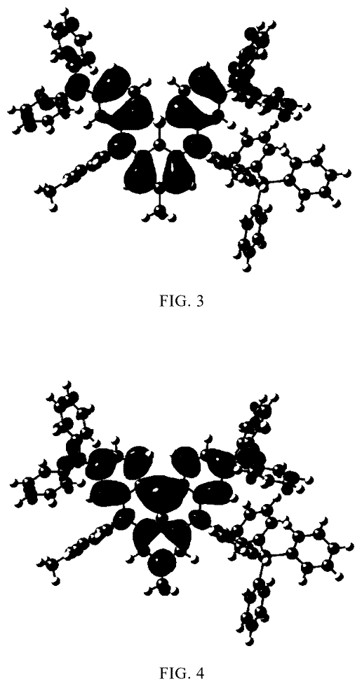

As an alternative, as shown in FIG. 1, the organic light-emitting diode device includes an electron injection layer (EIL), an electron transport layer (ETL) and/or a hole blocking layer (HBL), a luminescent layer (EML), an electron blocking layer (EBL) and/or a hole transport layer (HTL), and a hole injection layer (HIL) that are sequentially stacked, where a thickness of the electron injection layer (EIL) is in a range from 0 nm to 3 nm, a thickness of the electron transport layer (ETL) is in a range from 20 nm to 40 nm, a thickness of the hole blocking layer (HBL) is in a range from 0 nm to 10 nm, a thickness of the luminescent layer (EML) is in a range from 20 nm to 40 nm, a thickness of the electron blocking layer (EBL) is in a range from 0 nm to 10 nm, a thickness of the hole transport layer (HTL) is in a range from 100 nm to 200 nm, and a thickness of the hole injection layer (HIL) is in a range from 0 nm to 10 nm.

In some embodiments, when the thickness of each of the plurality of functional layers of the organic light-emitting diode device is changed in the above range, the color of the light emitted accordingly may be changed within the same color system. In some embodiments, the hole blocking layer may be the same layer as the electron transport layer.

In some embodiments, the electron blocking layer may be the same layer as the hole transport layer.

In some embodiments, as shown in FIG. 1, the organic light-emitting diode device includes a cathode, an electron injection layer (EIL), an electron transport layer (ETL), a hole blocking layer (HBL), a luminescent layer (EML), an electron blocking layer (EBL), a hole transport layer (HTL), a hole injection layer (HIL) and an anode that are sequentially stacked.

In some embodiments, the organic light-emitting diode device may include a cathode, an electron injection layer (EIL), an electron transport layer (ETL), a luminescent layer (EML), a hole transport layer (HTL), a hole injection layer (HIL) and an anode that are sequentially stacked.

In some embodiments, the cathode may be made of a metal material, such as any one of aluminum, magnesium, silver, indium, tin, and titanium or an alloy of two or more of aluminum, magnesium, silver, indium, tin, and titanium. The cathode may alternatively have a multi-layer structure made of metal and metal compound materials, such as any one or more of lithium fluoride/aluminum, lithium oxide/aluminum and barium fluoride/aluminum. In addition to the materials of the cathode listed above, the cathode may alternatively be made of materials that facilitate electron injection and combinations thereof, including materials known to be suitable as the cathode.

In some embodiments, the anode may be made of a metal material, such as any one of copper, gold, silver, iron, chromium, nickel, palladium, and platinum or an alloy of copper, gold, silver, iron, chromium, nickel, palladium, and platinum. The anode may alternatively be made of a metal oxide such as any one or more of indium oxide, zinc oxide, indium tin oxide (ITO), and indium zinc oxide (IZO). The anode may alternatively be made of a self-conductive polymer, such as any one or more of polyaniline, polypyrrole and poly (3-thiotolene). In addition to the materials of the anode listed above, the anode may alternatively be made of materials that facilitate hole injection and combinations thereof, including materials known to be suitable as the anode.

In some embodiments, the electron injection layer may be made of any one or more of an alkali metal material, a metal material, an alkali metal compound, and a metal compound, for example, any one or more of lithium fluoride (LiF), ytterbium (Yb), magnesium (Mg), and calcium (Ca).

In some embodiments, the electron transport layer/the hole blocking layer may be made of heterocyclic aromatic compounds, for example, imidazole derivatives such as benzimidazole derivatives, imidazopyridine derivatives, and benzimidazolophenanthidine derivatives; oxazine derivatives such as pyrimidine derivatives and triazine derivatives; compounds containing a nitrogen six-membered ring structure such as quinoline derivatives, isoquinoline derivatives, and phenanthroline derivatives, including compounds having a phosphine oxide-based substituent on the heterocyclic ring; or 2-(4-biphenylyl)-5-(4-tert-butylphenyl)-1, 3, 4-oxadiazole (PBD), 1, 3-bis[5-(p-tert-butylphenyl)-1, 3, 4-oxadiazole-2-yl]benzene (OXD-7), 3-(4-tert-butylphenyl)-4-phenyl-5-(4-biphenylyl)-1, 2, 4-Triazole (TAZ), 3-(4-tert-butylphenyl)-4-(4-ethylphenyl)-5-(4-biphenylyl)-1, 2, 4-triazole (p-EtTAZ), bathophenanthroline (BPhen), bathocuproin (BCP) or 4, 4′-bis(5-methylbenzoxazol-2-yl) stilbene (BzOs) or the like.

In some embodiments, the hole transport layer/the electron blocking layer may be made of an arylamine or carbazole material having a hole transport property, for example, 4,4′-bis[N-(1-naphthyl)-N-phenylamino]biphenyl (NPB), N,N′-bis(3-methylphenyl)-N, N′-diphenyl-[1,1′-biphenyl]-4, 4′-diamine (TPD), 4-phenyl-4′-(9-phenylfluoren-9-yl)triphenylamine (BAFLP), 4,4′-bis[N-(9, 9-dimethylfluoren-2-yl)-N-phenylamino]biphenyl (DFLDPBi), 4,4′-bis(9-carbazolyl) biphenyl (CBP), or 9-phenyl-3-[4-(10-phenyl-9-anthracenyl)phenyl]-9H-carbazole (PCzPA) or the like.

In some embodiments, the hole injection layer may be made of an inorganic oxide, such as any one or more of molybdenum oxide, titanium oxide, vanadium oxide, rhenium oxide, ruthenium oxide, chromium oxide, zirconium oxide, hafnium oxide, tantalum oxide, silver oxide, tungsten oxide, and manganese oxide; or p-type dopants of a strong electron-withdrawing system and dopants of a hole transport material, such as hexacyanohexaazatriphenylene, 2, 3, 5, 6-tetrafluoro-7, 7, 8, 8-tetracyanoquinodimethane (F4TCNQ), or 1, 2, 3-tris[(cyano) (4-cyano-2, 3, 5, 6-tetrafluorophenyl)methylene] cyclopropane, or the like.

The organic light-emitting diode device according to the embodiment of the present disclosure may be manufactured using a conventional method. For example, the functional layers may be formed by vacuum evaporation. An exemplary method for manufacturing an organic light-emitting diode device includes:

Cleaning an anode layer on a transparent glass substrate layer, drying the cleaned anode layer, placing the dried anode layer in a vacuum evaporation cavity, sequentially forming the functional layers such as the hole injection layer, the hole transport layer, the electron blocking layer, the luminescent layer, the hole blocking layer, the electron transport layer and the electron injection layer through evaporating on the anode layer when a vacuum degree reaches a set standard, and finally forming a cathode layer through evaporating, wherein a thickness of each functional layer may be determined according to the design structure of the organic light-emitting diode device. The luminescent layer at least includes a host and a dopant, and the host and the dopant may be mixed according to a proportion and then evaporated.

### Embodiment 1

The structure of the organic light-emitting diode device manufactured in the embodiment 1 is:

ITO/HIL:PD (5 nm, 98:2)/HTL (150 nm)/EBL (5 nm)/Host:boron-nitrogen-containing organic compound in formula 3 (30 nm, 85:15)/HBL (5 nm)/ETL:LIQ (30 nm, 1:1)/LIQ (1 nm)/Mg:Ag (120 nm, 9:1).

The boron-nitrogen-containing organic compound in the formula 3 is used as the dopant (the luminescent material) in the luminescent layer; the compounds used for the materials of the functional layers are as follows:

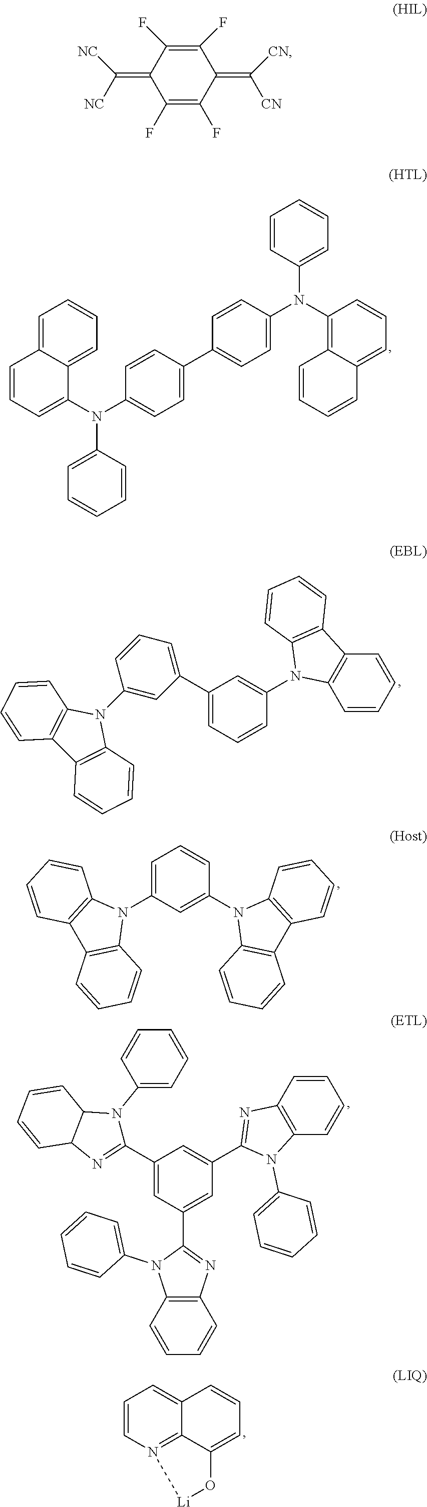

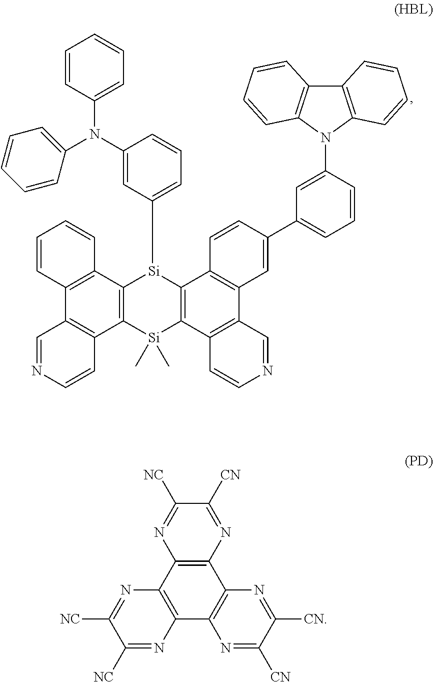

### Embodiment 2

The structure of the organic light-emitting diode device manufactured in the embodiment 2 is:

ITO/HIL:PD (5 nm, 98:2)/HTL (150 nm)/EBL (5 nm)/Host:boron-nitrogen-containing organic compound in formula 3:Dopant (35 nm, 75:15:10)/HBL (5 nm)/ETL:LIQ (30 nm, 1:1)/LIQ (1 nm)/Mg:Ag (120 nm, 9:1).

The boron-nitrogen-containing organic compound in the formula 3 is used as the co-doping material (the sensitizing material) in the luminescent layer to sensitize the luminescent material, and Dopant is a fluorescent material and is used as the dopant (the luminescent material); the compounds used for the materials of the functional layers are the same as in the embodiment 1, except for Dopant as follows:

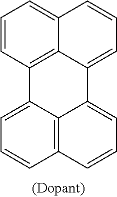 [SMILES: c1cc2cccc3c4cccc5cccc(c(c1)c23)c54]

### Embodiment 3

The structure of the organic light-emitting diode device manufactured in the embodiment 3 is:

ITO/HIL:PD 5 nm, 98:2)/HTL (150 nm)/EBL (5 nm)/Host:FB:boron-nitrogen-containing organic compound in formula 5:Dopant (35 nm, 75:20:5)/HBL (5 nm)/ETL:LIQ (30 nm, 1:1)/LIQ (1 nm)/Mg:Ag (120 nm, 9:1).

The boron-nitrogen-containing organic compound in the formula 5 is used as the dopant (the luminescent material) in the luminescent layer, and FB is the co-doping material (the sensitizing material) to sensitize the luminescent material; the compounds used for the materials of the functional layers are the same as in the embodiment 1, except for FB as follows:

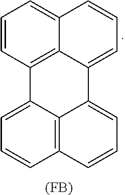

### Embodiment 4

The structure of the organic light-emitting diode device manufactured in the embodiment 4 is:

ITO/HIL:PD (5 nm, 98:2)/HTL (150 nm)/EBL (5 nm)/Host:boron-nitrogen-containing organic compound in formula 3:Dopant (35 nm, 70:15:15)/HBL (5 nm)/ETL:LIQ (30 nm, 1:1)/LIQ (1 nm)/Mg:Ag (120 nm, 9:1).

The boron-nitrogen-containing organic compound in the formula 3 is used as the co-doping material (the sensitizing material) in the luminescent layer to sensitize the luminescent material, and Dopant is a phosphorescent compound and is used as the dopant (the luminescent material); the compounds used for the materials of the functional layers are the same as in the embodiment 1, except for Dopant as follows:

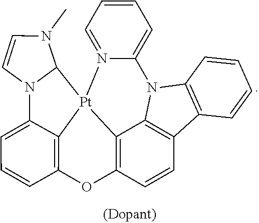

### Embodiment 5

The structure of the organic light-emitting diode device manufactured in the embodiment 5 is:

ITO/HIL:PD (5 nm, 98:2)/HTL (150 nm)/EBL (5 nm)/Host:PhB:boron-nitrogen-containing organic compound (400 nm, 75:15:10)/HBL (5 nm)/ETL:LIQ (30 nm, 1:1)/LIQ (1 nm)/Mg:Ag (120 nm, 9:1).

The boron-nitrogen-containing organic compound in the formula 3 is used as the dopant (the luminescent material) in the luminescent layer, PhB is a phosphorescent compound and is used as the co-doping material (the sensitizing material) to sensitize the luminescent material; the compounds used for the materials of the functional layers are the same as in the embodiment 1, except for PhB as follows:

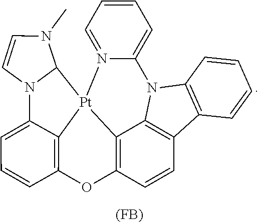

### Comparative Embodiment

The structure of the organic light-emitting diode device in the comparative embodiment is:

ITO/HIL:PD (5 nm, 98:2)/HTL (150 nm)/EBL (5 nm)/Host:PtON7-dtb (300 nm, 75:25)/HBL (5 nm)/ETL:LIQ (30 nm, 1:1)/LIQ (1 nm)/Mg:Ag (120 nm, 9:1).

The compounds used in the materials of the functional layers are the same as in the embodiment 1, except for PtON7-dtb as follows:

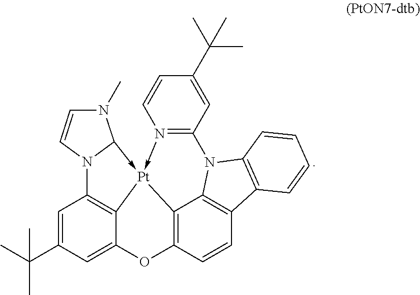

In some embodiments provided by the present disclosure, the performance parameters of the organic light-emitting diode device are shown in table 2.

TABLE 2
Performance parameters of the organic light-emitting diode device

| | | Luminescence | | | |
|---|---|---|---|---|---|
| Device | Voltage* | efficiency* | CIEX | CIEy | Lifetime* |
| Comparative | 4.9(V) | 8.5(cd/A) | 0.134 | 0.067 | 13.4 |
| embodiment | | | | | (LT95@1000 nit) |
| Embodiment 1 | 104% | 110% | 0.138 | 0.067 | 105% |
| Embodiment 2 | 102% | 108% | 0.136 | 0.065 | 105% |
| Embodiment 3 | 104% | 120% | 0.136 | 0.068 | 118% |
| Embodiment 4 | 101% | 150% | 0.134 | 0.067 | 120% |
| Embodiment 5 | 99% | 118% | 0.138 | 0.064 | 157% |

*The voltage, the luminescence efficiency, and the lifetime in the embodiments were calculated based on the comparative embodiment.

For the boron-nitrogen-containing organic compound provided by the embodiment of the present disclosure, by introducing the silicon-containing substituent into a molecular planar skeleton, the overlapping is avoided by the silicon-containing substituent between the dopant and another dopant and/or between the dopant and the host, the lifetime of the triplet excitons is shortened, thereby improving the luminescence efficiency of the organic light-emitting diode device and/or prolonging the lifetime of the organic light-emitting diode device. Meanwhile, the silicon-containing substituent has a small influence on the highest occupied molecular orbital (HOMO), the lowest unoccupied molecular orbital (LUMO), the triplet state (T1) and the singlet state (S1) of the boron-nitrogen-containing organic compound, and can occupy a wider space due to the fact that the silicon-carbon bond (Si—C) is longer than the carbon-carbon bond (C—C), so that the boron-nitrogen-containing organic compound has a more stereoscopic structure, and the luminescence efficiency and the lifetime of the organic light-emitting diode device are improved through the more stereoscopic structure.

Based on the same inventive concept, the present disclosure further provides an illumination or display apparatus including the above organic light-emitting diode device.

The illumination or display apparatus provided by the present disclosure includes the organic light-emitting diode device according to the above technical solution, so that the illumination or display apparatus provided by the present disclosure has all the beneficial effects of the organic light-emitting diode device, and details are not described herein.

In the description of the present specification, reference to the description of “one embodiment,” “some embodiments,” “an example,” “a specific example,” or “some examples” or the like means that a particular feature, structure, material, or characteristic described in connection with the embodiment or example is included in at least one embodiment or example of the present disclosure. In this specification, the schematic representations of the terms used above are not necessarily intended to refer to the same embodiment or example. Furthermore, the particular features, structures, materials, or characteristics described may be combined in any suitable manner in any one or more embodiments or examples. Furthermore, various embodiments or examples described in this specification can be associated and combined by one of ordinary skill in the art.

In addition, technical solutions between various embodiments may be combined with each other, but must be based on the realization of the technical solutions by one of ordinary skill in the art, and when the combined technical solutions are contradictory or cannot be realized, such a combination should not be considered to exist, and is not within the protection scope of the present disclosure.

While embodiments of the present disclosure have been shown and described, it will be understood by one of ordinary skill in the art that: numerous changes, modifications, substitutions and variations can be made to the embodiments without departing from the principles and spirit of the present disclosure, the scope of the present disclosure is defined by the claims and their equivalents.

1. A boron-nitrogen-containing organic compound, having a following structure in a general formula 1: 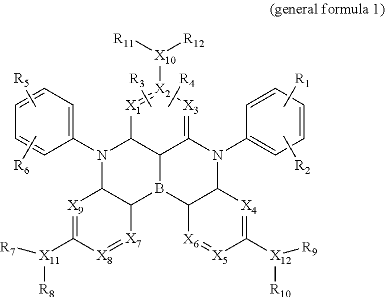
where, at least one of R₁ to R₁₂ is a silicon-containing substituent;
R₁ to R₁₂ are the same as each other or different from each other, and are each independently selected from hydrogen, a substituted or unsubstituted alkyl group having 1 to 40 carbon atoms, a substituted or unsubstituted aryl group having 6 to 40 carbon atoms, a substituted or unsubstituted heteroaryl group having 5 to 60 carbon atoms, a substituted or unsubstituted fluorenyl group, a substituted or unsubstituted heterofluorenyl group, a substituted or unsubstituted aryloxy group having 6 to 60 carbon atoms, a substituted or unsubstituted alkoxy group having 1 to 39 carbon atoms, a substituted or unsubstituted arylamine group having 6 to 39 carbon atoms, a substituted or unsubstituted cycloalkyl group having 3 to 39 carbon atoms, a substituted or unsubstituted heterocycloalkyl group having 3 to 39 carbon atoms, a substituted or unsubstituted alkylsilyl group having 1 to 39 carbon atoms, a substituted or unsubstituted alkylboryl group having 1 to 39 carbon atoms, a substituted or unsubstituted arylboryl group having 6 to 39 carbon atoms, a substituted or unsubstituted arylphosphino group having 6 to 39 carbon atoms, and a substituted or unsubstituted arylsilyl group having 6 to 39 carbon atoms;
R₁ and R₂ are bonded to form a ring, fused to form a ring, or do not form a ring, R₃ and R₄ are bonded to form a ring, fused to form a ring, or do not form a ring, R₅ and R₆ are bonded to form a ring, fused to form a ring, or do not form a ring, R₇ and R₈ are bonded to form a ring, fused to form a ring, or do not form a ring, R₉ and R₁₀ are bonded to form a ring, fused to form a ring, or do not form a ring, and R₁₁ and R₁₂ are bonded to form a ring, fused to form a ring, or do not form a ring;
X₁ to X₁₂ are the same as each other or different from each other, and are each independently selected from CH and N, and at least one of X₁₀ to X₁₂ is N; and
hydrogen in R₁ to R₁₂ and X₁ to X₁₂ is selected from any one or more of protium, deuterium and tritium.

2. The boron-nitrogen-containing organic compound according to claim 1, wherein in the general formula 1, R₁ to R₁₂ are independently selected from substituents containing 1 to 4 aromatic rings and/or aromatic heterocyclic rings.

3. The boron-nitrogen-containing organic compound according to claim 1, wherein in the general formula 1, R₁ and R₂ are bonded to form a 5 to 8-membered ring, and/or R₃ and R₄ are bonded to form a 5 to 8-membered ring, and/or R₅ and R₆ are bonded to form a 5 to 8-membered ring, and/or R₇ and R₈ are bonded to form a 5 to 8-membered ring, and/or R₉ and R₁₀ are bonded to form a 5 to 8-membered ring, and/or R₁₁ and R₁₂ are bonded to form a 5 to 8-membered ring.

4. The boron-nitrogen-containing organic compound according to claim 1, wherein in the general formula 1, X₁, X₃, X₄, X₅, X₈, X₉, X₁₀, X₁₁ and X₁₂ are the same as each other or different from each other, and are independently selected from CD and N.

5. The boron-nitrogen-containing organic compound according to claim 4, wherein in the general formula 1, X₂, X₆, and X₇ are the same as each other or different from each other, and are independently selected from CD and N.

6. The boron-nitrogen-containing organic compound according to claim 1, wherein the boron-nitrogen-containing organic compound has a structure as in a general formula 2 or 3: 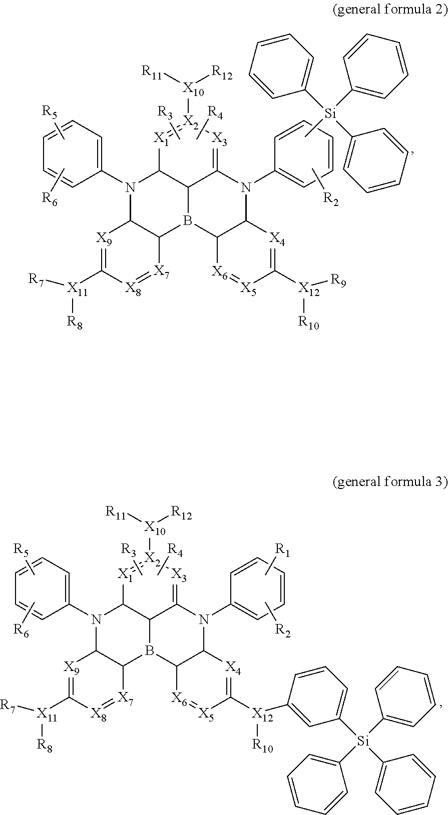
wherein in the general formulas 2 and 3, R₁ to R₁₂ and X₁ to X₁₂ are the same as those in the general formula 1.

7. The boron-nitrogen-containing organic compound according to claim 1, wherein a singlet (E_{S1})-triplet (E_{T1}) splitting energy (ΔEₛₜ) of the boron-nitrogen-containing organic compound is greater than 0 eV and less than 1.0 eV.

8. The boron-nitrogen-containing organic compound according to claim 7, wherein the boron-nitrogen-containing organic compound satisfies:
a triplet energy level (E_{T1}) is greater than or equal to 2.60 eV;
a triplet excitation wavelength (λ_{T1}) is less than or equal to 480 nm; and
a HOMO orbital energy level (E_{HOMO}) is greater than or equal to 4.60 eV.

9. The boron-nitrogen-containing organic compound according to claim 7, wherein the boron-nitrogen-containing organic compound is represented by any one of the following formulas 1 to 30:

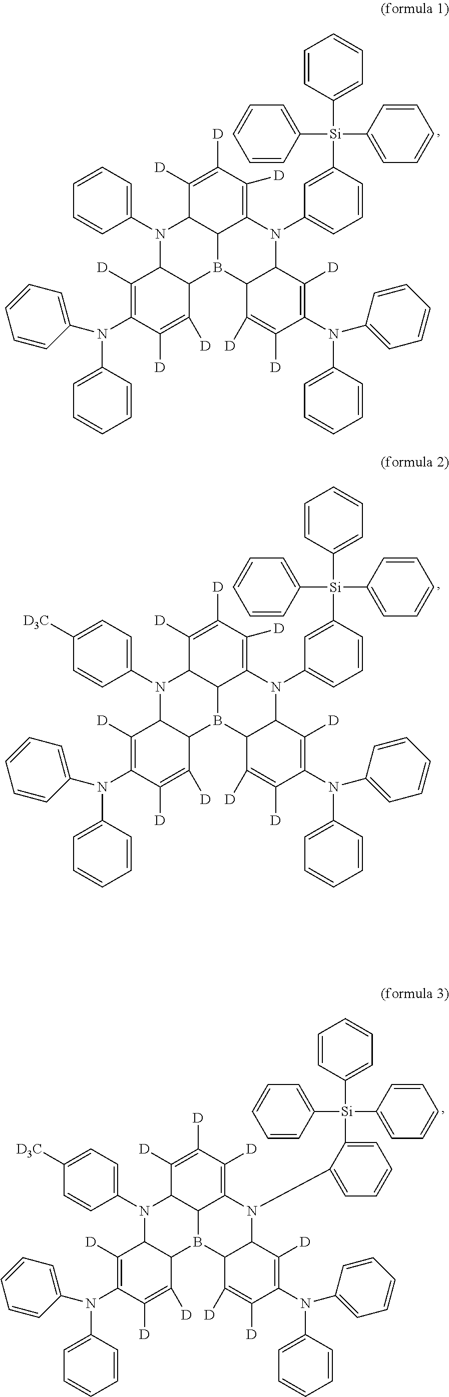

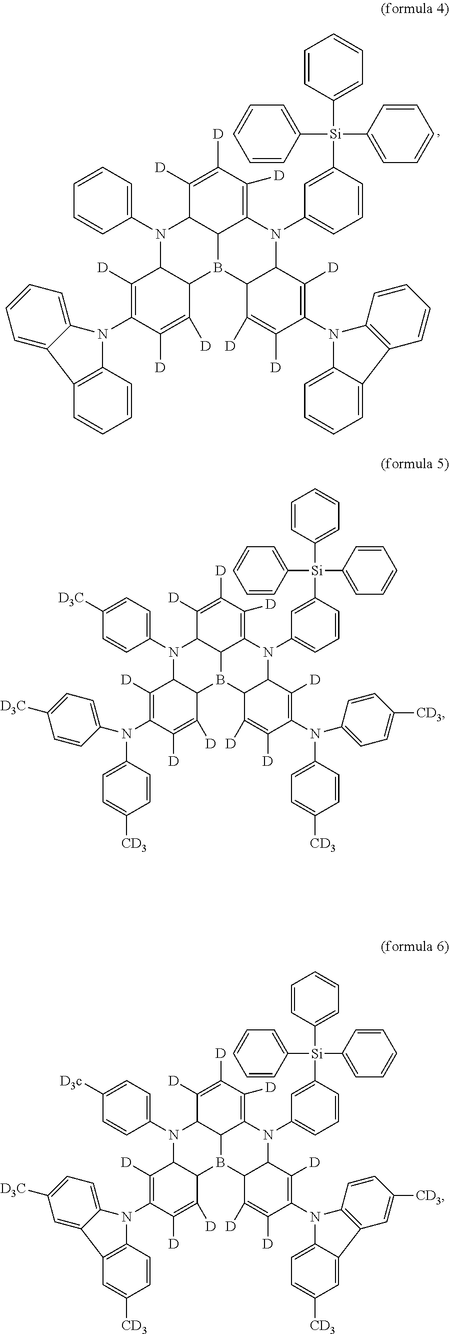

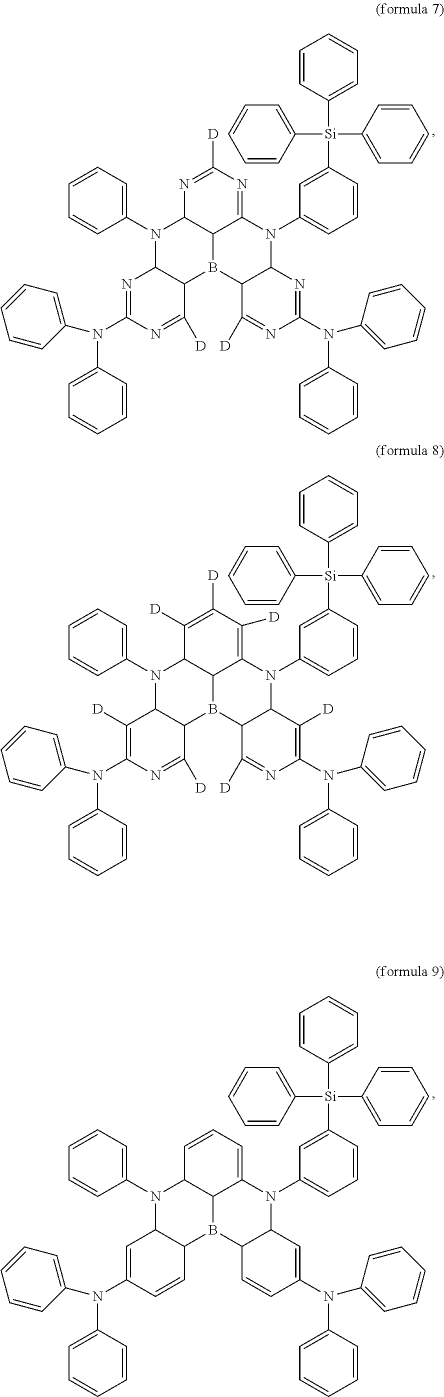

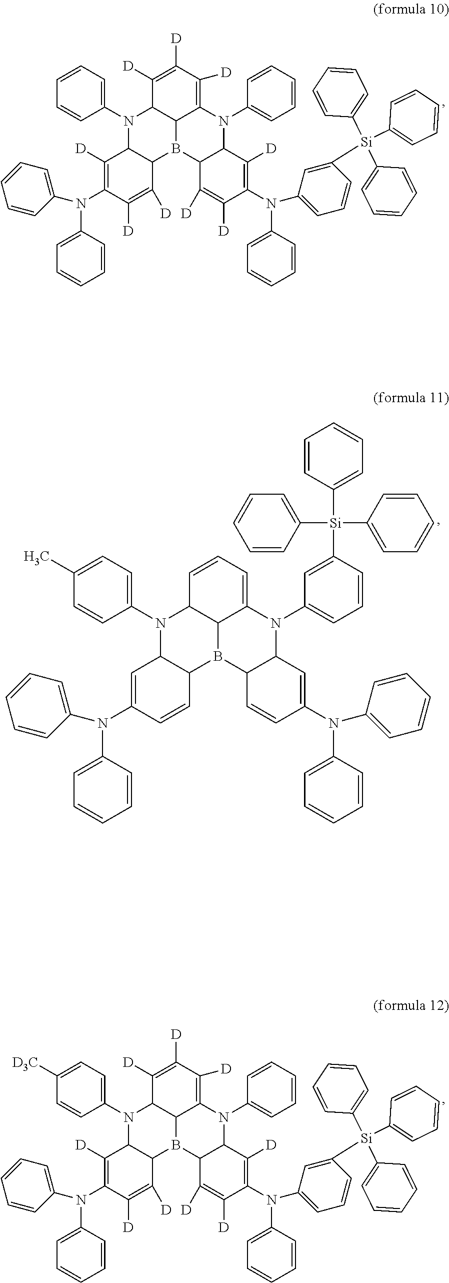

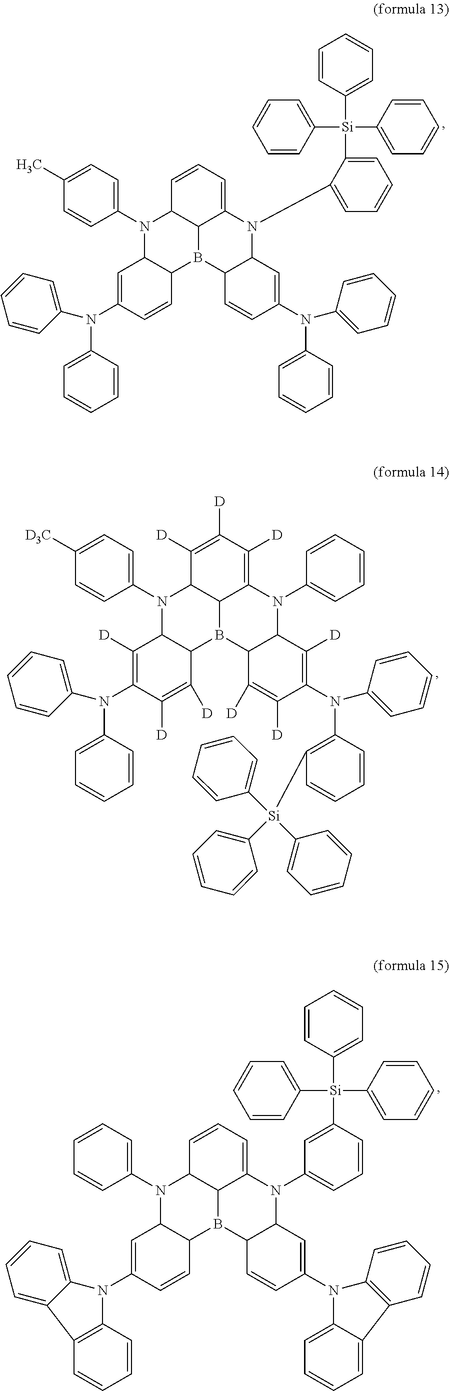 [SMILES: Cc1ccc(N2C3C=C(N(c4ccccc4)c4ccccc4)C=CC3B3C4C=CC(N(c5ccccc5)c5ccccc5)=CC4N(c4ccccc4[Si](c4ccccc4)(c4ccccc4)c4ccccc4)C4=CC=CC2C34)cc1 ; [2H]C1=C([2H])C2B3C4C([2H])=C([2H])C(N(c5ccccc5)c5ccccc5)=C([2H])C4N(c4ccc(C([2H])([2H])[2H])cc4)C4C([2H])=C([2H])C([2H])=C(C34)N(c3ccccc3)C2C([2H])=C1N(c1ccccc1)c1ccccc1[Si](c1ccccc1)(c1ccccc1)c1ccccc1 ; C1=CC2C3B(C4C=CC(n5c6ccccc6c6ccccc65)=CC4N(c4cccc([Si](c5ccccc5)(c5ccccc5)c5ccccc5)c4)C3=C1)C1C=CC(n3c4ccccc4c4ccccc43)=CC1N2c1ccccc1]

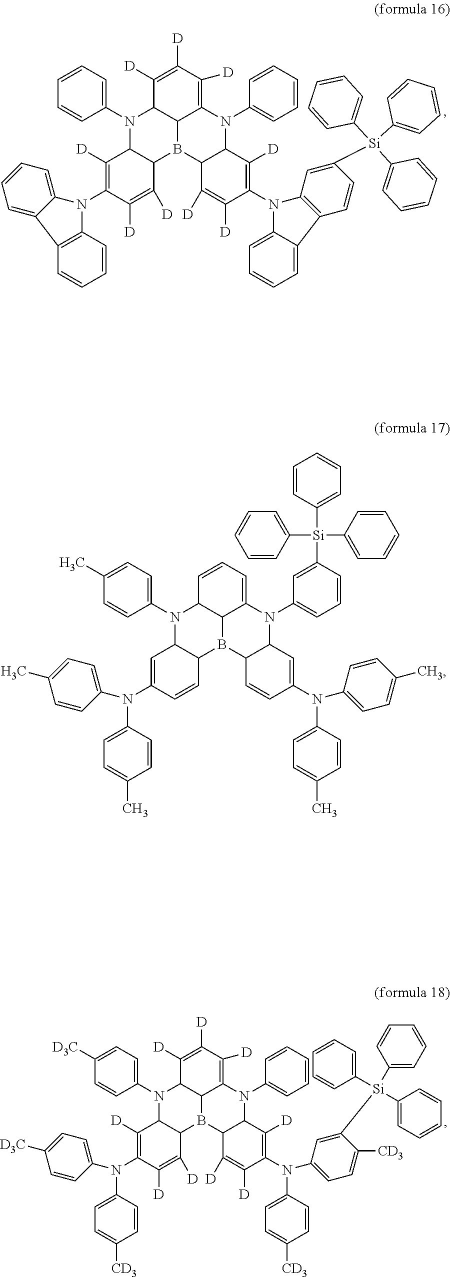

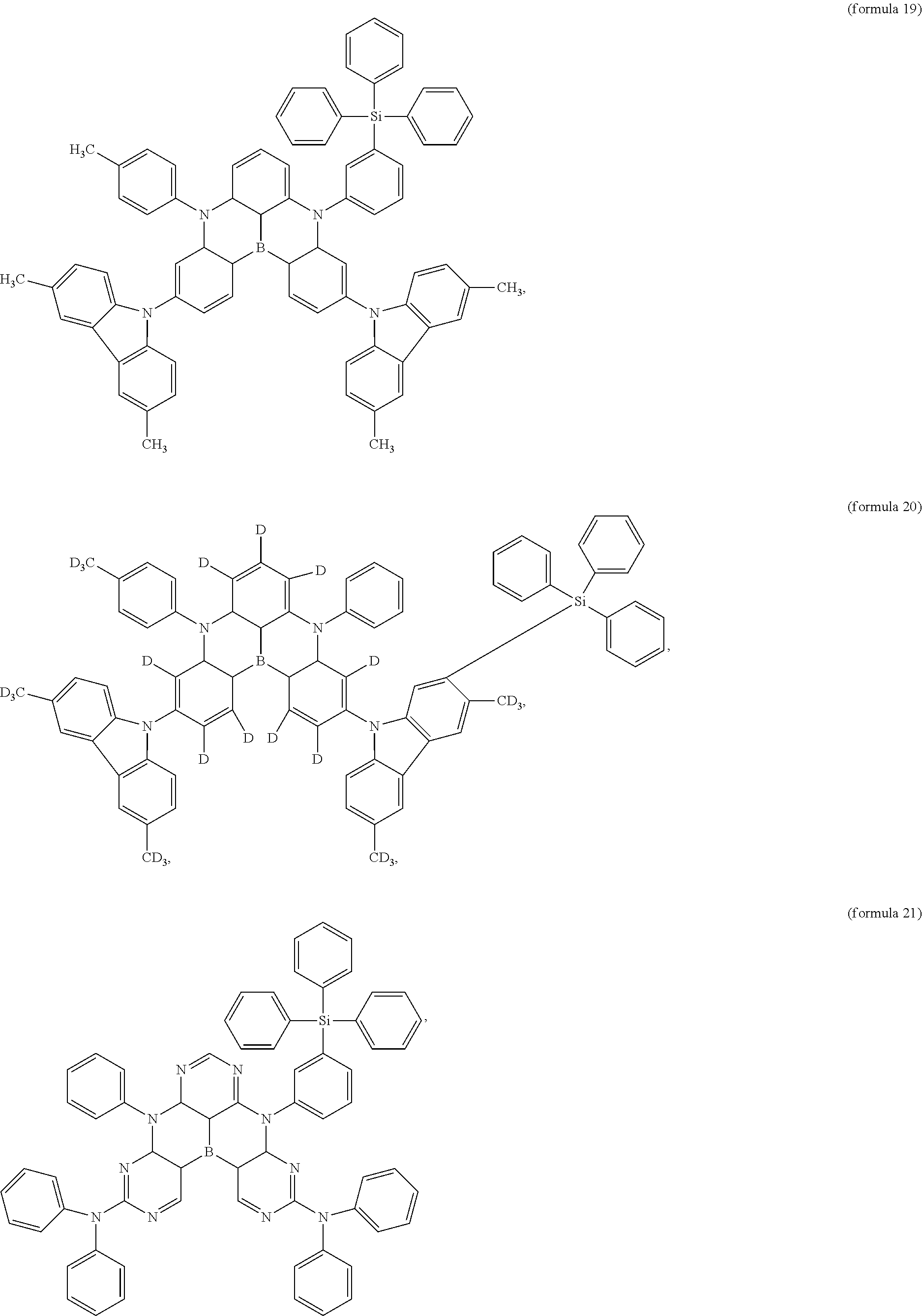

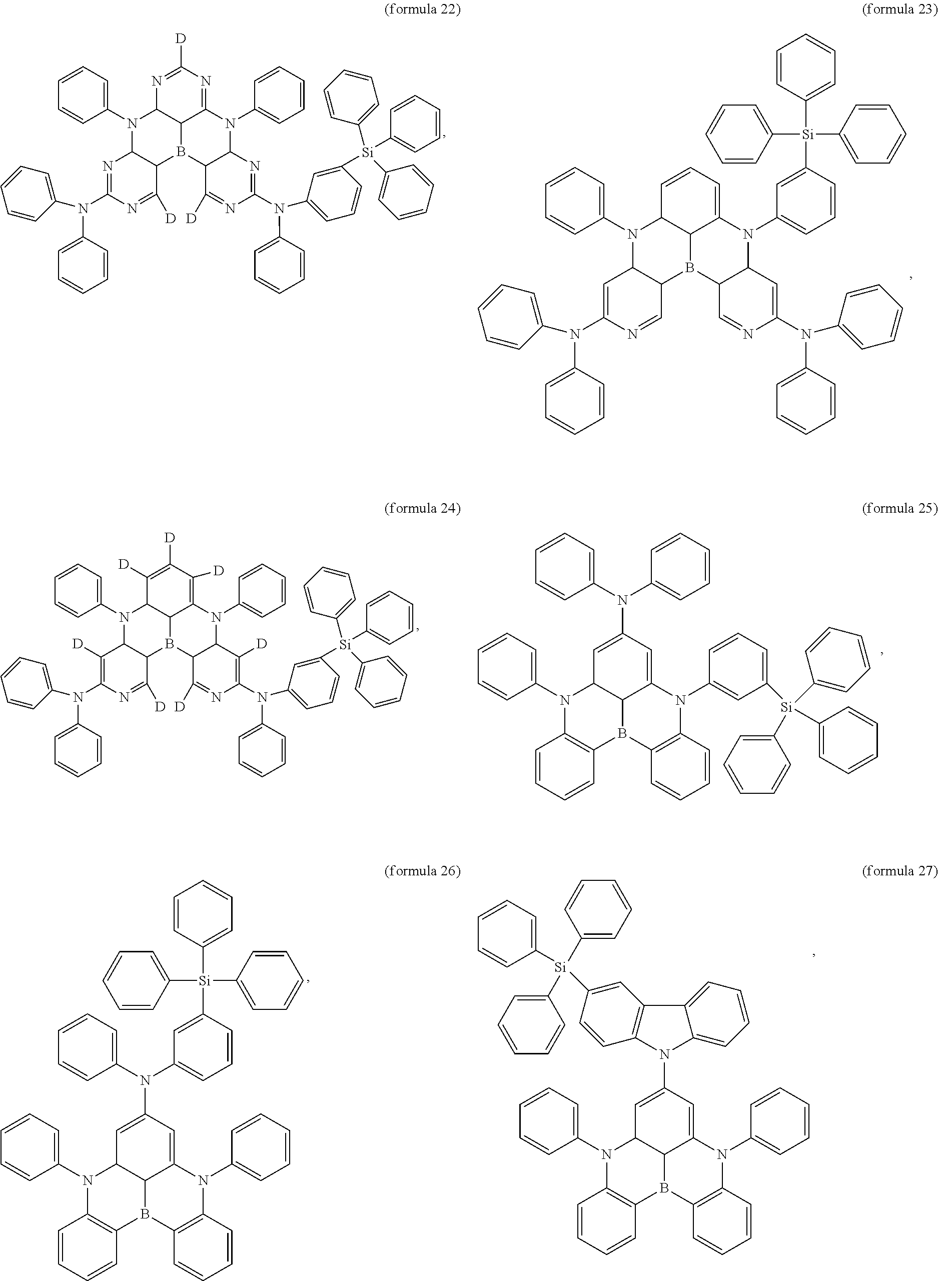

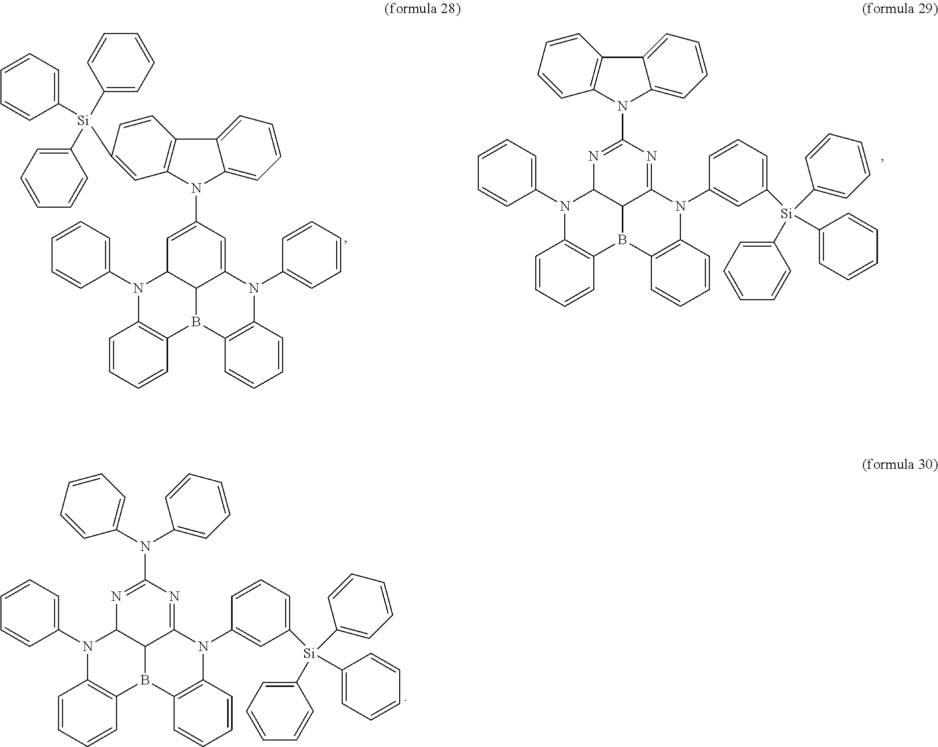 [SMILES: C1=C2C3B(c4ccccc4N2c2ccccc2)c2ccccc2N(c2ccccc2)C3C=C1n1c2ccccc2c2ccc([Si](c3ccccc3)(c3ccccc3)c3ccccc3)cc21 ; c1ccc(N2c3ccccc3B3c4ccccc4N(c4cccc([Si](c5ccccc5)(c5ccccc5)c5ccccc5)c4)C4=NC(n5c6ccccc6c6ccccc65)=NC2C34)cc1 ; c1ccc(N(C2=NC3C4B(c5ccccc5N(c5cccc([Si](c6ccccc6)(c6ccccc6)c6ccccc6)c5)C4=N2)c2ccccc2N3c2ccccc2)c2ccccc2)cc1]

10. An organic light-emitting diode device, wherein at least one functional layer of the organic light-emitting diode device comprises the boron-nitrogen-containing organic compound according to claim 1.

11. The organic light-emitting diode device according to claim 10, wherein the at least one functional layer comprises a luminescent layer comprising the boron-nitrogen-containing organic compound.

12. The organic light-emitting diode device according to claim 11, wherein the luminescent layer comprises a host and the boron-nitrogen-containing organic compound, and a mass ratio of the host to the boron-nitrogen-containing organic compound is (50 to 90):(0 to 5).

13. The organic light-emitting diode device according to claim 12, wherein the luminescent layer further comprises a functional material as a dopant or a co-doping material, and a mass ratio of the host, the boron-nitrogen-containing organic compound and the functional material is (50 to 90):(0 to 5):(10 to 40).

14. The organic light-emitting diode device according to claim 13, wherein the functional material is selected from compounds represented by formula 31 or formula 32:

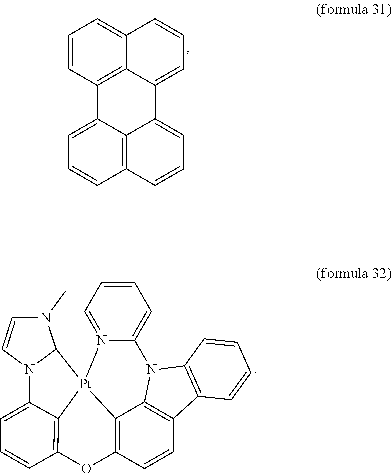

15. The organic light-emitting diode device according to claim 10, wherein the organic light-emitting diode device comprises an electron injection layer, an electron transport layer and/or a hole blocking layer, the luminescent layer, an electron blocking layer and/or a hole transport layer, and a hole injection layer that are sequentially stacked, where a thickness of the electron injection layer is in a range from 0 nm to 3 nm, a thickness of the electron transport layer is in a range from 20 nm to 40 nm, a thickness of the hole blocking layer is in a range from 0 nm to 10 nm, a thickness of the luminescent layer is in a range from 20 nm to 40 nm, a thickness of the electron blocking layer is in a range from 0 nm to 10 nm, a thickness of the hole transport layer is in a range from 100 nm to 200 nm, and a thickness of the hole injection layer is in a range from 0 nm to 10 nm.

16. An illumination or display apparatus, comprising the organic light-emitting diode device according to claim 10.

17. The boron-nitrogen-containing organic compound according to claim 2, wherein a singlet (E_{S1})-triplet (E_{T1}) splitting energy (ΔEₛₜ) of the boron-nitrogen-containing organic compound is greater than 0 eV and less than 1.0 eV.

18. The boron-nitrogen-containing organic compound according to claim 3, wherein a singlet (E_{S1})-triplet (E_{T1}) splitting energy (ΔEₛₜ) of the boron-nitrogen-containing organic compound is greater than 0 eV and less than 1.0 eV.

19. The boron-nitrogen-containing organic compound according to claim 4, wherein a singlet (E_{S1})-triplet (E_{T1}) splitting energy (ΔEₛₜ) of the boron-nitrogen-containing organic compound is greater than 0 eV and less than 1.0 eV.

20. The boron-nitrogen-containing organic compound according to claim 5, wherein a singlet (E_{S1})-triplet (E_{T1}) splitting energy (ΔEₛₜ) of the boron-nitrogen-containing organic compound is greater than 0 eV and less than 1.0 eV.
